(19) United States
(12) Patent Application Publication
(10) Pub. No.: US 2025/0056932 A1
(43) Pub. Date: Feb. 13, 2025

(54) Display Device and Method of Manufacturing Display Device

(71) Applicant: LG Display Co., Ltd., Seoul (KR)

(72) Inventors: Hyun Chyol Shin, Paju-si (KR); Seong Soo Cho, Paju-si (KR); Hee Won Lee, Paju-si (KR); Han Saem Kang, Paju-si (KR); Sang Hak Shin, Paju-si (KR); Hyoung Sun Park, Paju-si (KR); Hyun Seok Na, Paju-si (KR); Jin Hwa Shin, Paju-si (KR); Joon Kwon Moon, Paju-si (KR)

(21) Appl. No.: 18/798,591

(22) Filed: Aug. 8, 2024

(30) Foreign Application Priority Data
Aug. 9, 2023 (KR) 10-2023-0104258

(51) Int. Cl. H01L 33/46; H01L 25/075; H01L 33/62

(52) U.S. Cl. CPC H01L 33/46; H01L 25/0753; H01L 33/62; H01L 2933/0025; H01L 2933/0066

(57) ABSTRACT

Disclosed are a display device and a method of manufacturing the display device. The display device includes a display panel on which a plurality of sub-pixels and lines connected to the sub-pixels and a driving circuit configured to drive the sub-pixels. The display panel further includes a plurality of protruded bank patterns disposed in the sub-pixels, and a light emitting element disposed in each of the bank patterns. The light emitting element includes a first electrode, a second electrode, a light emitting layer disposed between the first electrode and the second electrode, and a reflector that covers side surfaces of the light emitting layer and at least a portion of side surfaces of the first electrode. The reflector includes a first insulating layer, a second insulating layer, and a metal layer disposed between the first insulating layer and the second insulating layer.

### CROSS-REFERENCE TO RELATED APPLICATION

This application claims priority to and the benefit of Republic of Korea Patent Application No. 10-2023-0104258, filed on Aug. 9, 2023, which is incorporated herein by reference in its entirety.

### BACKGROUND

### Technical Field

The present disclosure relates to a display device and a method of manufacturing the display device.

### Related Art

Electroluminescent display devices may be classified into organic light emitting diode (OLED) display devices in which OLEDs are disposed in pixels, and inorganic light emitting display devices (hereinafter referred to as “display devices”) in which inorganic light emitting diodes (hereinafter referred to as “LEDs”) are disposed in pixels.

Since electroluminescent display devices display images using self-luminous elements, the electroluminescent display devices do not require a separate light source, such as a backlight unit, and thus can be implemented in various thin forms. Since the electroluminescent display devices have a fast response time, high luminous efficiency and brightness, and a wide viewing angle and may express a black gradation in perfect black, the electroluminescent display devices have an excellent contrast ratio and an excellent color gamut.

The OLED display devices require a design for preventing or at least reducing the permeation of oxygen and moisture because an oxidation phenomenon between an organic light emitting layer and an electrode may occur due to the permeation of moisture and oxygen.

As an example of display devices, micro LED display devices in which micro LEDs are disposed in pixels have been attracting attention as a next-generation display device. A micro LED may be an inorganic LED with a size of 100 μm or less. Micro LEDs may be manufactured separately by a semiconductor process, transferred to pixels located on a display panel substrate of the display device, and disposed in sub-pixels for each color.

### SUMMARY

In a process of manufacturing a display device, defects may be continuously caused by a narrow margin when a reflective layer is formed on a bank pattern that is a transfer structure of micro light emitting diodes (LEDs). Therefore, light efficiency can be degraded when the reflective layer is formed under the micro LED.

The present specification is directed to solving the above-described necessity and/or problems.

The present specification is also directed to providing a display device in which a reflective layer is provided inside a light emitting element to allow light to be directly reflected through the reflective layer in the light emitting element, thereby increasing luminous efficiency, and a method of manufacturing the display device.

The objects of the present disclosure are not limited to the above-described objects, and other objects that are not mentioned will be able to be clearly understood by those skilled in the art from the following description.

A display device according to one or more embodiments of the present specification may include a display panel on which a plurality of sub-pixels and lines connected to the sub-pixels are disposed, and a pixel driving circuit configured to drive the sub-pixels, wherein the display panel further includes a plurality of protruded bank patterns disposed in the sub-pixels, and a light emitting element disposed in each of the bank patterns, the light emitting element includes a first electrode, a second electrode, a light emitting layer disposed between the first electrode and the second electrode, and a reflector that covers side surfaces of the light emitting layer and at least a portion of side surfaces of the first electrode, and the reflector includes a first insulating layer, a second insulating layer, and a metal layer disposed between the first insulating layer and the second insulating layer.

A method of manufacturing a display device may include forming a display panel on which a plurality of sub-pixels and lines connected to the sub-pixels are disposed, and forming a pixel driving circuit configured to drive the sub-pixels, wherein the forming of the display panel further includes forming a plurality of protruded bank patterns disposed in the sub-pixels, and forming a light emitting element disposed in each of the bank patterns, the forming of the light emitting element includes forming a first electrode and a second electrode, forming a light emitting layer disposed between the first electrode and the second electrode, and forming a reflector that covers side surfaces of the light emitting layer and at least a portion of side surfaces of the first electrode, and the forming of the reflector includes forming a first insulating layer and a second insulating layer on side surfaces of the light emitting element, and forming a metal layer between the first insulating layer and the second insulating layer.

In the present disclosure, a reflective layer may be formed in the light emitting element so that light may be directly reflected in the light emitting element, thereby increasing light emission efficiency. In particular, an embodiment of the present disclosure may increase the internal light emission efficiency of the light emitting element by placing the reflective layer inside the light emitting element, thereby increasing the light emission efficiency even with low power consumption, thereby improving yield.

In the present disclosure, since the process of forming a reflective mirror on the upper portion of the bank pattern may be omitted, the process may be simplified, and process margin defects may be fundamentally improved.

The present specification may increase light emission efficiency by arranging a reflective layer inside a light emitting element, thereby reducing process materials since a side wall diffuser made of an expensive material having excellent light emission efficiency is not required.

In addition, one embodiment of the disclosure can simplify the manufacturing process by omitting a patterning process of forming a reflective layer under the light emitting element to form a reflective mirror.

Moreover, one embodiment of the disclosure can reduce manufacturing process costs by placing a reflective layer in the light emitting element to increase light emission efficiency without using an expensive side wall diffuser material.

The effects of the present disclosure are not limited to the above-mentioned effects, and other effects not mentioned will be clearly understood by those skilled in the art from the description of the claims.

### BRIEF DESCRIPTION OF THE DRAWINGS

FIG. 1 is a view showing a display device according to one embodiment of the present disclosure.

FIG. 2 is an enlarged view of area A in FIG. 1 according to one embodiment of the present disclosure.

FIG. 3 is a view showing a partial area of a pixel according to one embodiment of the present disclosure.

FIG. 4 is a cross-sectional view along line I-I′ in FIG. 3 according to one embodiment of the present disclosure according to one embodiment of the present disclosure.

FIG. 5 is a cross-sectional view along line II-II′ in FIG. 3 according to one embodiment of the present disclosure.

FIG. 6 is a cross-sectional view along line III-III′ in FIG. 3 according to one embodiment of the present disclosure.

FIG. 7 is a cross-sectional view showing an example in which a main light emitting element and a sub light emitting element are electrically connected to a pixel driving circuit.

FIG. 8 is a view showing a display device according to another embodiment of the present disclosure.

FIG. 9 is a cross-sectional view along line IV-IV′ in FIG. 8 according to one embodiment of the present disclosure.

FIG. 10 is a cross-sectional view showing a longitudinal cross-sectional structure of a portion of the display device along line I-I′ in FIG. 1, which is an enlarged cross-sectional view of “B” in FIG. 4 according to one embodiment of the present disclosure.

FIG. 11 is a cross-sectional view showing a longitudinal cross-sectional structure of a portion of the display device along line I-I′ in FIG. 1, which is an enlarged cross-sectional view of “C” in FIG. 4 according to one embodiment of the present disclosure.

FIG. 12 is a plan view showing a light emitting element of the display device according to one embodiment of the present specification.

FIG. 13 is a cross-sectional view showing a longitudinal cross-sectional structure of a portion of the light emitting element along line V-V′ in FIG. 12 according to one embodiment of the present disclosure.

FIGS. 14A to 14T are cross-sectional views showing a process of manufacturing the light emitting element of the display device according to one embodiment of the present specification.

FIG. 15 is a plan view showing a light emitting element of the display device according to another embodiment of the present specification.

FIG. 16 is a cross-sectional view showing a longitudinal cross-sectional structure of a portion of the light emitting element along line VI-VI′ in FIG. 15 according to one embodiment of the present disclosure.

FIGS. 17A to 17T are cross-sectional views showing a process of manufacturing the light emitting element of the display device according to another embodiment of the present specification.

FIGS. 18A to 18G are cross-sectional views for describing a process of manufacturing one pixel having the light emitting element of the display device according to one embodiment of the present specification.

FIG. 19 is a cross-sectional view schematically showing a state in which light is reflected in and emitted from the light emitting element of the display device according to one embodiment of the present specification.

FIG. 20 is a cross-sectional view schematically showing a state in which light is reflected in and emitted from the light emitting element of the display device according to another embodiment of the present specification.

### DETAILED DESCRIPTION

Advantages and features of embodiments of the present specification and methods of achieving them will become clear with reference to embodiments described below in detail in conjunction with the accompanying drawings. The present disclosure is not limited to the embodiments disclosed below but can be implemented in various different forms, these embodiments are merely provided to make the disclosure of the present disclosure complete and fully inform those skilled in the art to which the present disclosure pertains of the scope of the present disclosure, and the present disclosure is only defined by the scope of the appended claims.

Since shapes, sizes, ratios, angles, numbers, and the like disclosed in the drawings for describing the embodiments of the present specification are illustrative, the present disclosure is not limited to the shown items. The same reference number indicates the same components throughout the specification. In addition, in describing the present disclosure, when it is determined that the detailed description of a related known technology may unnecessarily obscure the gist of the present disclosure, detailed description thereof will be omitted.

When the terms “comprise,” “include,” and “have,” described in the present specification are used, other parts may be added unless “only” is used. When a component is expressed in the singular, it can be construed as a plurality of components unless specifically stated otherwise.

In construing a component, the component is construed as including the margin of error even when there is no separate explicit description.

When the position relationship and interconnection relationship between two components, such as “on,” “above,” “under,” “next to,” “connected or coupled,” “crossing or intersecting,” or the like described, one or more other components may be interposed between the components unless the term “immediately” or “directly” is described.

When the temporal relationship is described using the term “after,” “subsequently,” “then,” “before,” or the like, it may include a non-consecutive case unless the term “immediately” or “directly” is used.

To distinguish components, “first,” “second,” and the like may be used in front of the names of the components, but functions or structures thereof are not limited by the ordinal numbers or component names. For convenience of description, the ordinal number of the names of the same components may be different between embodiments.

The following embodiments may be partially or fully coupled or combined, and various technological interworking and driving are possible. The embodiments may be implemented independently of each other and implemented together in the associated relationship.

Hereinafter, various embodiments of the present disclosure will be described in detail with reference to the accompanying drawings.

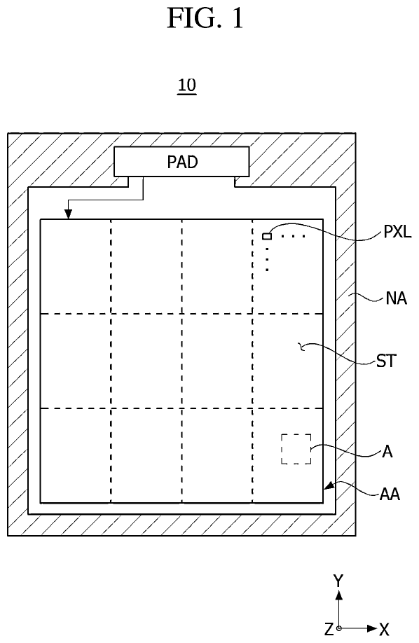

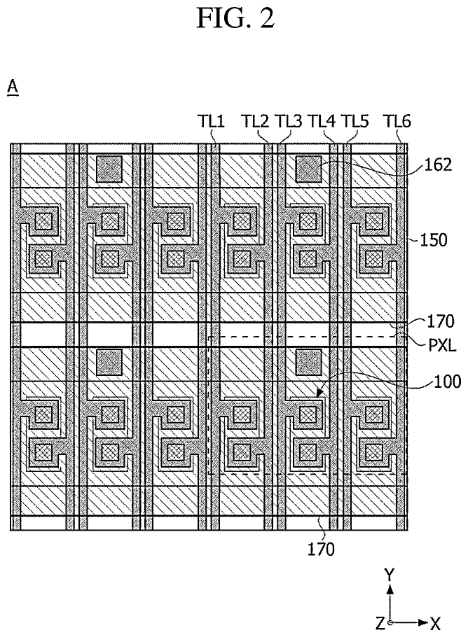

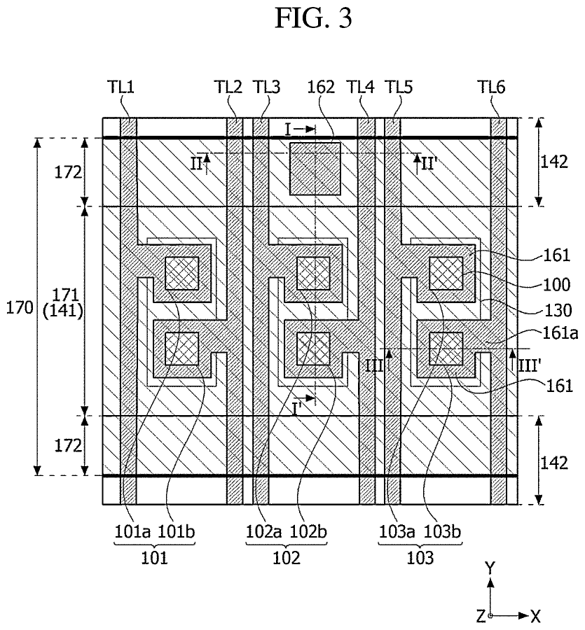

FIG. 1 is a view showing a display device according to one embodiment of the present disclosure. FIG. 2 is an enlarged view of area A in FIG. 1. FIG. 3 is a view showing a partial area of a pixel.

Referring to FIGS. 1 and 2, a display device 10 according to the embodiment of the present disclosure includes a display panel that visually displays input images. The display panel may include a display area AA in which images are displayed and a non-display area NA in which the images are not displayed. Various lines and driving circuits may be installed in the non-display area NA, and a pad part PAD to which integrated circuits, printed circuits, and the like are connected.

A plurality of light emitting elements 100 (which may also be referred to as light emitting devices) disposed in the display area AA to form pixel PXLs may be micro-sized inorganic light emitting elements. The inorganic light emitting element may be grown on a silicon wafer and then attached to the display panel through a transfer process.

The transfer process of the light emitting element 100 may be performed for each pre-divided area. Although FIG. 1 shows that the display area AA is divided into nine transfer areas ST, the sizes or number of divisions of the transfer areas is not limited thereto. The transfer process may be performed sequentially or simultaneously on the first to ninth transfer areas STs. The blue light emitting element 100, the green light emitting element 100, and the red light emitting element 100 may each be sequentially transferred to the transfer areas STs.

A data driving circuit or a gate driving circuit may be disposed in the non-display area NA, and lines through which control signals for controlling the driving circuits are supplied may be disposed. Here, the control signals may include various timing signals including a clock signal, an input data enable signal, and synchronization signals and may be received through the pad part PAD.

The pixels PXLs may be driven by the pixel driving circuit. The pixel driving circuit may drive the plurality of pixels by receiving a driving voltage, image signals (digital signals), synchronization signals synchronized with the image signals, and the like and outputting anode voltages and a cathode voltage of the light emitting element 10. The driving voltage may be a high potential voltage EVDD. The cathode voltage may be a low potential voltage EVSS commonly applied to the pixels. The anode voltage may be a voltage corresponding to a pixel data value of the image signal. The pixel driving circuit may be disposed in the non-display area NA or under the display area AA.

Each of the pixels PXLs may include a plurality of sub-pixels each having a different color. For example, the plurality of pixels may include a red sub-pixel in which the light emitting element 100 for emitting light having a red wavelength is disposed, a green sub-pixel in which the light emitting element 100 for emitting light having a green wavelength is disposed, and a blue sub-pixel in which the light emitting element 100 for emitting light having a blue wavelength is disposed. The plurality of pixels may further include white pixels.

Referring to FIGS. 2 and 3, the plurality of pixels PXLs may be consecutively disposed in a first direction (X-axis direction) and a second direction (Y-axis direction). A plurality of sub-pixels in the same color may be disposed in the pixel of the display area AA. For example, each of the plurality of sub-pixels may include a first red sub-pixel in which a 1-1 light emitting element 101a for emitting light having the red wavelength is disposed, a second red sub-pixel in which a 1-2 light emitting element 101b for emitting light having the red wavelength is disposed, a first green sub-pixel in which a 2-1 light emitting element 102a for emitting light having the green wavelength is disposed, a second green sub-pixel in which a 2-2 light emitting element 102b for emitting light having the green wavelength is disposed, a first blue sub-pixel in which a 3-1 light emitting element 103a for emitting light having the blue wavelength is disposed, and a second blue sub-pixel in which a 3-2 light emitting element 103b for emitting light having the blue wavelength is disposed. The 1-1 light emitting element 101a, the 2-1 light emitting element 102a, and the 3-1 light emitting element 103a may be construed as main light emitting elements.

The 1-2 light emitting element 101b, the 2-2 light emitting element 102b, and the 3-2 light emitting element 103b may be construed as sub light emitting elements.

Since one sub-pixel may include one or more light emitting elements, when one light emitting element fails, the brightness of the sub-pixel may be adjusted by increasing the brightness of the remaining light emitting elements. However, the present disclosure is not necessarily limited thereto, and one sub-pixel may include only one light emitting element.

A plurality of first electrodes 161 may each be disposed under the light emitting element 100 and may be selectively connected to a plurality of signal lines TL1 to TL6 by connection portion 161a. The high potential voltage may be applied to the pixel driving circuit through the signal lines TL to TL6. The signal lines TL to TL6 and the first electrodes 161 may be formed as electrode patterns integrated with anodes during an electrode patterning process.

As an example, the first signal line TL1 may be connected to an anode of the first red sub-pixel, and the second signal line TL2 may be connected to an anode of the second red sub-pixel. The third signal line TL3 may be connected to an anode of the first green sub-pixel, and the fourth signal line TL4 may be connected to an anode of the second green sub-pixel. The fifth signal line TL5 may be connected to an anode of the first blue sub-pixel, and the sixth signal line TL6 may be connected to an anode of the second blue sub-pixel. When one sub-pixel includes only one light emitting element, the number of signal lines TL may be reduced by half.

The second electrode 170 may be a cathode that is disposed in each row to apply the cathode voltage to the light emitting elements 100 consecutively disposed in the first direction (X-axis direction). The plurality of second electrodes 170 may be disposed to be spaced apart from each other in the second direction (Y-axis direction). The plurality of second electrodes 170 may be connected to the cathode voltage through contact electrodes 162. The plurality of second electrodes 170 may each be electrically connected to the contact electrode 162. However, the present disclosure is not limited thereto, and the second electrode 170 is not divided into a plurality of electrodes and may be formed as one electrode layer serving as a common electrode.

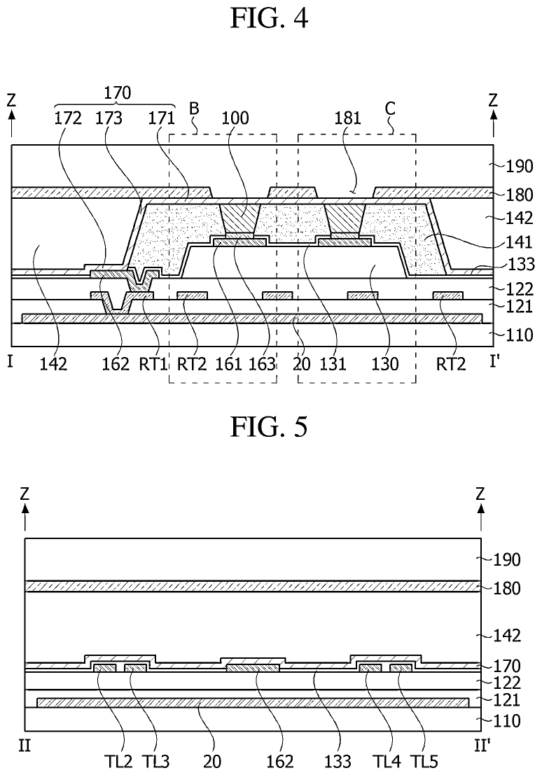

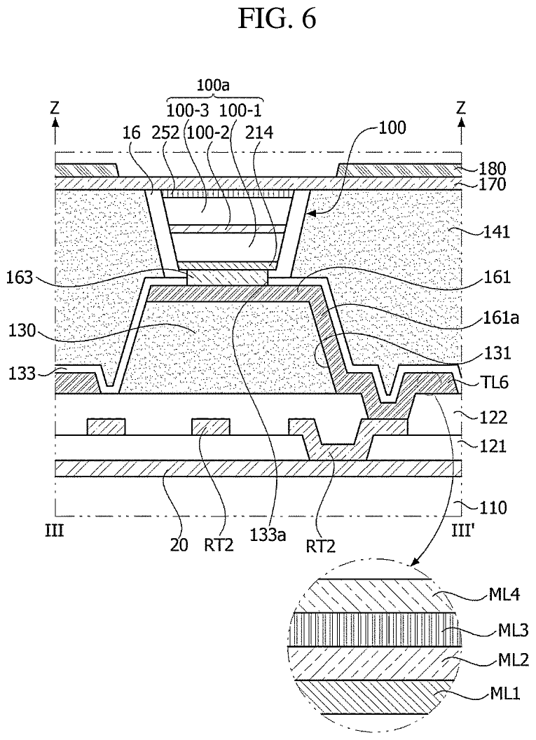

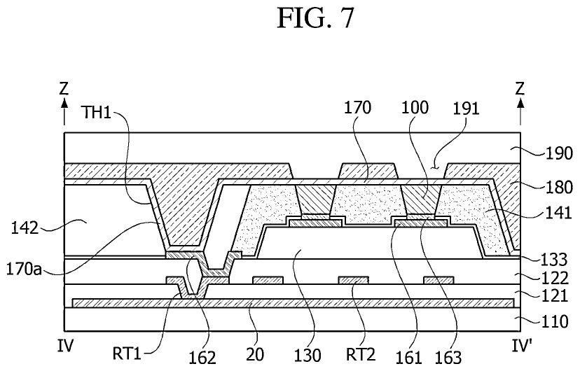

FIG. 4 is a cross-sectional view along line I-I′ in FIG. 3. FIG. 5 is a cross-sectional view along line II-II′ in FIG. 3. FIG. 6 is a cross-sectional view along line III-III′ in FIG. 3. FIG. 7 is a cross-sectional view showing an example in which two light emitting elements are connected to a pixel driving circuit.

Referring to FIGS. 3 to 5, the display device 10 according to the embodiment includes a plurality of first electrodes 161 and contact electrodes 162 that are disposed on a substrate 110, a plurality of light emitting elements 100 disposed on the plurality of first electrodes 161, a first interlayer insulating layer 141 disposed between the plurality of light emitting elements 100, and a second electrode 170 disposed on the plurality of light emitting elements 100.

The substrate 110 may be made of flexible plastic. For example, the substrate 110 may be manufactured as a single-layer or multilayered substrate 110 made of a material selected from the group consisting of polyimide, polyethylene terephthalate, polyethylene naphthalate, polycarbonate, polyethersulfone, polyarylate, polysulfone, and a cyclic-olefin copolymer, but is not limited thereto. For example, the substrate 110 may be a ceramic or glass substrate.

A pixel driving circuit 20 may be disposed in the display area AA on the substrate 110. The pixel driving circuit 20 may include a plurality of thin film transistors (TFTs) using an amorphous silicon semiconductor, a polycrystalline silicon semiconductor, or an oxide semiconductor.

The pixel driving circuit 20 may include at least one driving TFT, at least one switching TFT, and at least one storage capacitor. When the pixel driving circuit 20 includes a plurality of TFTs, the pixel driving circuit 20 may be formed on the substrate 110 by a process of manufacturing the TFT. In an embodiment, the pixel driving circuit 20 may be a concept that collectively indicates the plurality of TFTs electrically connected to the light emitting element 100.

The pixel driving circuit 20 may be a driving driver manufactured on the single crystal semiconductor substrate 110 using a process of manufacturing a metal-oxide-silicon field effect transistor (MOSFET). The driving driver may include a plurality of pixel driving circuits and drive a plurality of sub-pixels. When the pixel driving circuit 20 is implemented as the driving driver, after an adhesive layer is disposed on the substrate 110, the driving driver may be mounted on the adhesive layer by the transfer process.

A buffer layer 121 that covers the pixel driving circuit 20 may be disposed on the substrate 110. The buffer layer 121 may be made of an organic insulating material, such as photosensitive photo acryl or photosensitive polyimide, but is not limited thereto.

The buffer layer 121 may use an inorganic insulating material, such as silicon nitride (SiNx) or silicon oxide (SiO2), in a manner of stacking the inorganic insulating material in multiple layers, and use an organic insulating material and an inorganic insulating material in a manner of stacking the organic insulating material and the inorganic insulating material in multiple layers.

An insulating layer 122 may be disposed on the buffer layer 121. The insulating layer 122 may be made of an organic insulating material, such as photosensitive photo acryl or photosensitive polyimide, but is not limited thereto. Connection lines RT1 and RT2 may be disposed on the buffer layer 121. The connection lines RT1 and RT2 may be connected to the corresponding signal lines TL1 to TL6 or connected to the signal lines TL1 to TL6. The connection lines RT1 and RT2 may include a plurality of line patterns disposed on different layers with one or more insulating layers interposed there between. The line patterns disposed on different layers may be electrically connected through contact holes passing through the insulating layers.

A plurality of bank patterns 130 may be disposed on the insulating layer 122. At least one light emitting element 100 may be disposed on each bank pattern 130. For example, a first light emitting element 101 may be disposed on the first bank pattern 130, a second light emitting element 102 may be disposed on the second bank pattern 130, and a third light emitting element 103 may be disposed on the third bank pattern 130.

The bank pattern 130 may be made of an organic insulating material, such as photosensitive photo acryl or photosensitive polyimide, but is not limited thereto. The bank pattern 130 may guide an attachment position of the light emitting element 100 in the transfer process of the light emitting element 100. The bank pattern 130 may be omitted.

A solder pattern 163 may be disposed on the first electrode 161. The solder pattern 163 may be made of indium (In), tin (Sn), or an alloy thereof, but is not limited thereto.

The plurality of light emitting elements 100 may each be installed on the solder pattern 163. One pixel may include light emitting elements 100 in three colors. The first light emitting element 101 may be a red light emitting element, the second light emitting element 102 may be a green light emitting element, and the third light emitting element 103 may be a blue light emitting element. Two light emitting elements may be formed on each sub-pixel.

The first interlayer insulating layer 141 may cover the plurality of light emitting elements 100 and bank patterns 130. Therefore, the first interlayer insulating layer 141 may cover a space between the plurality of light emitting elements 100 and a space between the bank patterns 130. The first interlayer insulating layers 141 may extend in the first direction X and may be spaced apart from each other in the second direction Y to be separated between the rows of the pixels.

The first interlayer insulating layer 141 may include an inorganic insulating material or an organic insulating material.

The second electrode 170 may be disposed on the plurality of light emitting elements 100. The second electrode 170 may be commonly connected to the plurality of pixels PXLs. The second electrode 170 may be a thin electrode through which light is transmitted. The second electrode 170 may be made of a transparent electrode material, such as indium tin oxide (ITO), but is not necessarily limited thereto.

The second electrodes 170 may extend in the first direction (X-axis direction) and may be spaced apart from each other in the second direction (Y-axis direction). The second electrode 170 may include a first area 171 disposed on an upper surface of the light emitting element 10 and an upper surface of the first interlayer insulating layer 141, a second area 172 in contact with the contact electrode 162 and electrically connected to the contact electrode 162, and a third area 173 disposed on side surfaces of the first interlayer insulating layer 141 to connect the first area 171 with the second area 172.

In a plan view, the plurality of second electrodes 170 may each overlap the first interlayer insulating layer 141, and the second area 172 may cover an outer surface of the first interlayer insulating layer 141.

A second interlayer insulating layer 142 may be an inorganic insulating material layer or an organic insulating material layer that surrounds the periphery of the first interlayer insulating layer 141. The second interlayer insulating layer 142 together with the first interlayer insulating layer 141 may be disposed on the insulating layer 122. The first interlayer insulating layer 141 and the second interlayer insulating layer 142 may be made of the same material among the inorganic insulating material and the organic insulating material or made of different materials. However, the present disclosure is not necessarily limited thereto.

According to the embodiment, since the second area 172 of the second electrode 170 is connected to the contact electrode 162 in a state of being entirely formed flat, stress is not excessively concentrated on a point at which the second area 172 is connected to the contact electrode 162. Therefore, it is possible to effectively prevent or at least reduce the occurrence of cracks in the second electrode 170.

The second interlayer insulating layer 142 may cover the second area 172 and the third area 173 of the second electrode 170. An upper surface of the second interlayer insulating layer 142 may be disposed coplanar with an upper surface of the first area 171 of the second electrode 170. In other words, the first interlayer insulating layer 141 and the second interlayer insulating layer 142 may serve as planarization layers. Therefore, since there is no step on a surface on which a black matrix 180 is formed, patterns of the black matrix 180 may be easily formed on the first interlayer insulating layer 141 and the second interlayer insulating layer 142. However, the present disclosure is not necessarily limited thereto, and the upper surfaces of the second interlayer insulating layer 142 and the second electrode 170 may have different heights.

The black matrix 180 may be made of an organic insulating material to which black pigment is added. The second electrode 170 may be in contact with the contact electrode 162 under the black matrix 180. A transmission hole 181 through which light emitted from the light emitting element 100 is emitted externally may be formed between the patterns of the black matrix 180. The black matrix 180 may solve a problem that light emitted from neighboring light emitting elements 100 is mixed by the first interlayer insulating layer 141.

A cover layer 190 may be made of an organic insulating material that covers the black matrix 180 and the second electrode 170. However, the present disclosure is not necessarily limited thereto.

In FIG. 3, configurations of the black matrix 180 and the cover layer 190 are omitted.

The contact electrode 162 may be electrically connected to the first connection line RT1 disposed thereunder, and the first connection line RT1 may be connected to the pixel driving circuit 20. Therefore, the cathode voltage may be applied to the second electrode 170 through the contact electrode 162. The first electrode 161 may be electrically connected to the second connection line RT2.

Referring to FIG. 5, the contact electrode 162 may be disposed coplanar with the signal lines TL1 to TL6. The pixel driving circuit 20 may be disposed under the contact electrode 162 and the signal lines TL1 to TL6. When the pixel driving circuit 20 is a driving driver, a plurality of driving drivers may be disposed in the display panel.

A second insulating layer 133 may expose the contact electrode 162 to allow the contact electrode 162 and the second electrode 170 to be connected electrically. In addition, the second insulating layer 133 may insulate the signal lines TL2 to TL5 and the second electrode 170.

Referring to FIG. 6, a connection portion 161a of the first electrode 161 (which may also be referred to as an extension) may extend to one side surface 131 of the bank pattern 130 and may be electrically connected to the connection line RT2 disposed on the insulating layer 122.

The first electrode 161, the connection portion 161a, the signal line TL, and/or the connection lines RT1 and RT2 may include a single or multi metal layer formed of materials selected from the group consisting of titanium (Ti), molybdenum (Mo), and aluminum (Al). The first electrode 161, the connection portion 161a, the signal line TL, and/or the connection line RT2 may be formed in a multilayered structure including a first layer ML1, a second layer ML2, a third layer ML3, and a fourth layer ML4.

The first layer ML1 and the third layer ML3 may include Ti or Mo. The second layer ML2 may include Al. The fourth layer ML4 may include a transparent conductive oxide layer, such as ITO or indium zinc oxide (IZO), which has high adhesion to the solder pattern 163 and also has corrosion resistance and acid resistance.

The first layer ML1, the second layer ML2, the third layer ML3, and the fourth layer ML4 may be sequentially deposited and then patterned by performing a photolithography process and an etching process.

The second insulating layer 133 may include an opening hole 133a disposed on the first electrode 161 and the signal line TL to expose the solder pattern 163.

The light emitting element 100 may include a first conductive semiconductor layer 100-1, an active layer 100-2 disposed on the first conductive semiconductor layer 100-1, and a second conductive semiconductor layer 100-3 disposed on the active layer 100-2. A first electrode 214 may be disposed under the first conductive semiconductor layer 100-1, and a second electrode 252 may be disposed on the second conductive semiconductor layer 100-3.

The light emitting element 100 may be formed on a silicon wafer using a metal organic chemical vapor deposition (MOCVD) method, a CVD method, a plasma-enhanced CVD (PECVD) method, a molecular beam epitaxy (MBE) method, a hydride vapor phase epitaxy (HVPE) method, a sputtering method, or the like.

The first conductive semiconductor layer 100-1 can be implemented using group III-V or group II-VI compound semiconductors and doped with a first dopant. The first conductive semiconductor layer 100-1 may be made of a semiconductor material with a composition formula of Alx1Iny1Ga(1-x1-y1)N (0≤x1≤1, 0≤y1≤1, 0≤x1+y1≤1) or any one or more among InAlGaN, AlGaAs, GaP, GaAs, GaAsP, and AlGaInP, but is not limited thereto. When the first dopant is an n-type dopant, such as Si, Ge, Sn, Se, or Te, the first conductive semiconductor layer 100-1 may be an n-type nitride semiconductor layer. However, when the first dopant is a p-type dopant, the first conductive semiconductor layer 100-1 may be a p-type nitride semiconductor layer.

The active layer 100-2 is a layer in which electrons (or holes) injected through the first conductive semiconductor layer 100-1 meet holes (or electrons) injected through the second conductive semiconductor layer 100-3. The active layer 100-2 may be transitioned to a low energy level as electrons and holes recombine and generate light having the corresponding wavelength.

The active layer 100-2 may have any one of a single well structure, a multi-well structure, a single quantum well structure, a multi quantum well (MQW) structure, a quantum dot structure, and a quantum line structure, and the structure of the active layer 100-2 is not limited thereto. The active layer 100-2 may generate light in the visible ray wavelength band. As an example, the active layer 100-2 may output light in any one of blue, green, and red wavelength bands.

The second conductive semiconductor layer 100-3 may be disposed on the active layer 100-2. The second conductive semiconductor layer 100-3 may be implemented using group III-V or group II-VI compound semiconductors, and the second conductive semiconductor layer 100-3 may be doped with a second dopant. The second conductive semiconductor layer 100-3 may be made of a semiconductor material with a composition formula of Inx2Aly2Ga(1-x2-y2)N (0≤x2≤1, 0≤y2≤1, 0≤x2+y2≤1) or a material selected from the group consisting of AlInN, AlGaAs, GaP, GaAs, GaAsP, and AlGaInP, but is not limited thereto. When the second dopant is a p-type dopant, such as Mg, Zn, Ca, Sr, or Ba, the second conductive semiconductor layer 100-3 doped with the second dopant may be a p-type semiconductor layer. When the second dopant is an n-type dopant, the second conductive semiconductor layer 100-3 may be an n-type nitride semiconductor layer.

A reflector 16 may be disposed on side surfaces and a lower surface of the light emitting element 100. The reflector 16 may have a structure in which a reflective material is dispersed in a resin layer, but is not necessarily limited thereto. As an example, the reflector 16 may be formed as a reflector with any of various structures. Light emitted from the active layer 100-2 may be reflected upward by the reflector 16, thereby increasing light extraction efficiency.

Although it has been described in the embodiment that the light emitting element 10 has a vertical structure in which lower and upper electrodes 214 and 252 are disposed above and under the light emitting structure, the light emitting element may have a lateral structure or a flip chip structure other than the vertical structure.

Referring to FIG. 7, the main light emitting element 102a and the sub light emitting element 102b of the sub-pixel may be disposed on the bank pattern 130. An example of the second light emitting element will be described. A 1-1 electrode 161-1 connected to the main light emitting element 102a may extend to one side surface of the bank pattern 130 and may be electrically connected to the 2-1 connection line RT21 disposed thereunder. A 1-2 electrode 161-2 connected to the sub light emitting element 102b may extend to the other side surface of the bank pattern 130 and may be electrically connected to the 2-2 connection line RT22 disposed thereunder.

The pixel driving circuit 20 may apply the anode voltage to the main light emitting element 102a through the 2-1 connection line RT21 and apply the anode voltage to the sub light emitting element 102b through the 2-2 connection line RT22. The pixel driving circuit 20 may apply the cathode voltage to the main light emitting element 102a and the sub light emitting element 102b through the first connection line RT1 and the second electrode 170.

The pixel driving circuit 20 may adjust brightness by driving only the main light emitting element 102a and adjust brightness by simultaneously driving the main light emitting element 102a and the sub light emitting element 102b. When the main light emitting element 102a becomes a dark spot, the pixel driving circuit 20 may adjust brightness by driving only the sub light emitting element 102b.

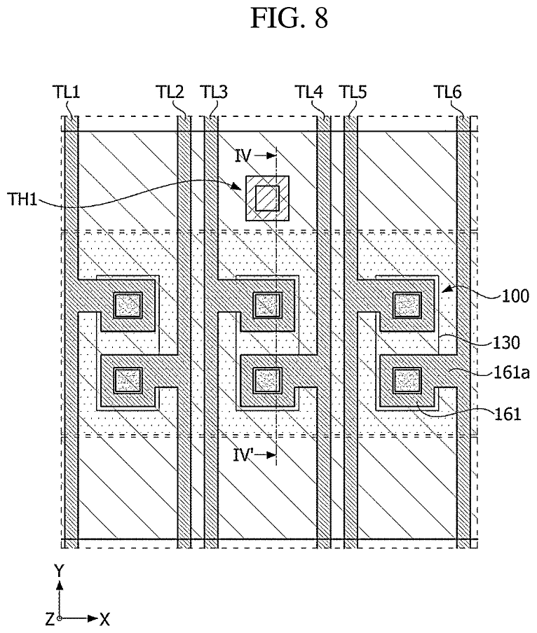

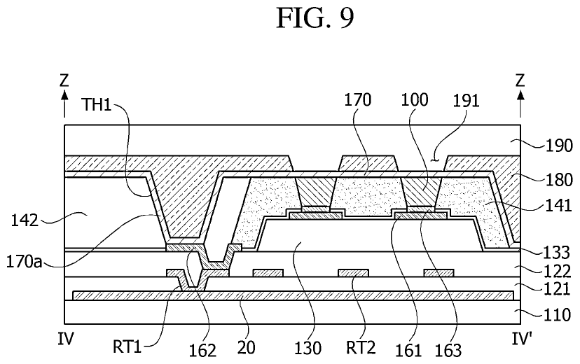

FIG. 8 is a view showing a display device according to another embodiment of the present disclosure. FIG. 9 is a cross-sectional view along line IV-IV in FIG. 8.

Referring to FIGS. 8 and 9, the second electrode 170 may be electrically connected to the contact electrode 162 through a contact hole TH1 formed in the second interlayer insulating layer 142. The second interlayer insulating layer 142 may include the contact hole TH1 that exposes the contact electrode 162. The second electrode 170 may be inserted into the contact hole TH1 of the second interlayer insulating layer 142 and may be in contact with an upper surface of the contact electrode 162. The contact hole TH1 may be formed in an outer area of the pixel.

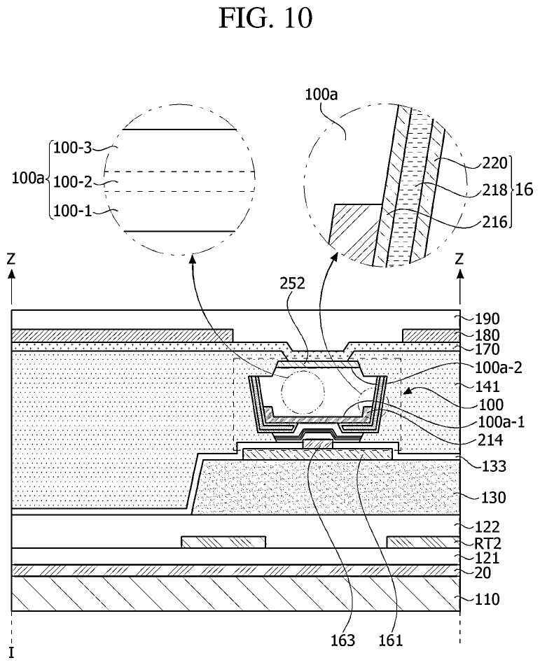

FIG. 10 is a cross-sectional view showing a longitudinal cross-sectional structure of a portion of the display panel along line I-I′ in FIG. 1, which is an enlarged cross-sectional view of “B” in FIG. 4 according to one embodiment.

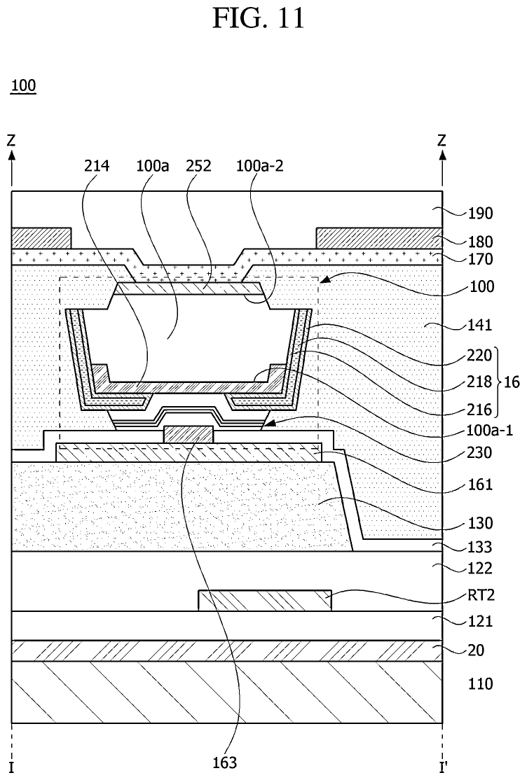

FIG. 11 is a cross-sectional view showing a longitudinal cross-sectional structure of a portion of the display panel along line I-I′ in FIG. 1, which is an enlarged cross-sectional view of “C” in FIG. 4 according to one embodiment.

Referring to FIGS. 10 and 11, the display device 10 according to the present embodiment may include the pixel driving circuit 20 formed on the substrate 110, the buffer layer 121 disposed on the pixel driving circuit 20, the connection lines RT1 and RT2 disposed on the buffer layer 121, the insulating layer 122 disposed on the connection lines RT1 and RT2, the bank pattern 130 disposed on the insulating layer 122, the first electrode 161 disposed above the bank pattern 130, and the light emitting element 100 disposed and bonded on the first electrode 161 and connected to the first electrode 161 through the solder pattern 163.

The light emitting element 100 emits light by recombination of electrons and holes according to a current flowing between the first conductive semiconductor layer 100-1 and the second conductive semiconductor layer 100-3.

The lower electrode 214 of each of the light emitting elements 100 may be electrically connected to an anode voltage output terminal of the pixel driving circuit 20 via the solder pattern 163, the first electrode 161, and at least one line pattern through a pad pattern 230 formed on a lower surface thereof.

The second electrode 170 of each of the light emitting elements 100 may be electrically connected to a cathode voltage output terminal of the pixel driving circuit 20 via the upper electrode 252 and one or more connection lines RT1 and RT2.

Under the upper surfaces of the light emitting elements 100, the bank pattern 130 and the light emitting elements 100 may be covered by the first interlayer insulating layer 141. The first interlayer insulating layer 141 may have a stacked structure of any one or more of an organic insulating material and an inorganic insulating material including an oxide film or a nitride film.

A second passivation layer 220 (see FIG. 4) made of an inorganic insulating material or an organic insulating material may be further formed to surround the periphery of the first interlayer insulating layer 141. The second interlayer insulating layer 142 together with the first interlayer insulating layer 141 may be disposed on the first insulating layer 122.

The second electrode 170 may be disposed on the first interlayer insulating layer 141 and commonly connected to all pixels PXLs. The second electrode 170 may be a thin metal electrode through which light is transmitted. The first electrode 161, the second electrode 170, and the black matrix 180 may be stacked in the non-emission area of the pixel area. The second electrode 170 may be made of a transparent electrode material, such as ITO, but is not necessarily limited thereto.

The first electrode 161 may be formed as a single or multilayered metal layer formed of materials selected from the group consisting of Ti, Mo, and Al. A transparent electrode material layer formed of a material selected between ITO and IZO may be stacked on the metal layer.

The black matrix 180 may be made of an organic insulating material to which black pigment is added. The second electrode 170 may be in contact with the contact electrode 162 under the black matrix 180.

The first interlayer insulating layer 141 may include a contact hole (not shown) that exposes the contact electrode 162. A portion of the second electrode 170 may be formed in the contact hole of the first interlayer insulating layer 141 so that the second electrode 170 may be in contact with the upper surface of the contact electrode 162. The contact hole (not shown) may be formed in the outer area of the pixel in the form of surrounding the bank patterns 130.

The cover layer 190 may be made of an organic insulating material that covers the black matrix 180 and the second electrode 170. An insulating layer that is the same as the first interlayer insulating layer 141 may be formed flat between the cover layer 190 and the second electrode 170. In this case, a passivation layer (not shown) made of an inorganic insulating material or an organic insulating material may cover the second electrode 170 in a smaller thickness than the first interlayer insulating layer 141.

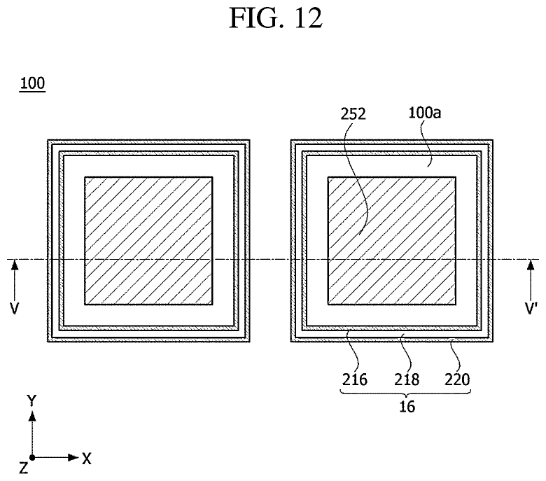

FIG. 12 is a plan view showing a light emitting element of the display panel according to one embodiment of the present specification.

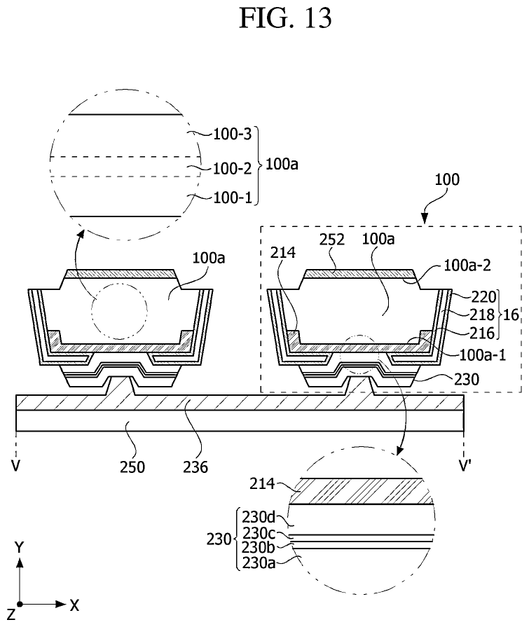

FIG. 13 is a cross-sectional view showing a longitudinal cross-sectional structure of a portion of the light emitting element along line V-V′ in FIG. 12 according to one embodiment.

Referring to FIGS. 12 and 13, the light emitting element 100 according to the embodiment of the present specification may be disposed by being transferred onto the bank pattern (not shown, 130 in FIG. 10) disposed on the substrate (not shown, 110 in FIG. 10) and overlap the bank pattern 130.

In addition, the light emitting element 100 may be in contact with the first electrode (not shown, 161 in FIG. 10) disposed on the bank pattern 130 and overlap the first electrode 161.

The light emitting element 100 may include a lower surface of the light emitting layer 100a on which the lower electrode 214 is disposed, an upper surface of the light emitting layer 100a on which the upper electrode 252 is disposed, and side surfaces of the light emitting layer 100a between the lower surface and the upper surface.

First and second flat protrusions 100a-1 and 100a-2 on which the lower electrode 214 and the upper electrode 252 are disposed may be formed on the lower and upper surfaces of the light emitting layer 100a. Stepped portions (not shown) may be formed on the side surfaces of the first and second flat protrusions 100a-1 and 100a-2.

The stepped portions have smaller heights than the first and second flat protrusions 100a-1 and 100a-2, and the reflector 16 may be disposed on at least a portion of side surfaces of the light emitting element 100 under the stepped portions.

An area of the light emitting element 100 may be smaller than or equal to areas of the bank pattern 130 and the first electrode 161. However, the present disclosure is not necessarily limited thereto. For a process margin, the area of the first electrode 161 may be preferably greater than the area of the light emitting element 100.

As shown in FIG. 10, the light emitting element 100 may include the light emitting layer 100a including the first conductive semiconductor layer 100-1, the second conductive semiconductor layer 100-3, and the active layer 100-2 interposed therebetween, the lower electrode 214 in contact with the first conductive semiconductor layer 100-1 of the light emitting layer 100a, the upper electrode 252 in contact with the second conductive semiconductor layer 100-3 of the light emitting layer 100a, and the reflector 16 covering the side surfaces and lower surfaces of the light emitting layer 100a and the lower electrode 214.

The reflector 16 may include first and second passivation layers 216 and 220 that surround the light emitting layer 100a and the lower electrode 214, and a reflective layer 218 disposed there between.

The first and second passivation layers 216 and 220 may be used as insulating layers or protective layers.

The lower electrode 214 in contact with the first conductive semiconductor layer 100-1 may include an anode, and the upper electrode 252 in contact with the second conductive semiconductor layer 100-3 may include a cathode. The light emitting layer 100a may include one or more quantum well layers. The doped first and second conductive semiconductor layers 100-1 and 100-3 and the active layer 100-2 of the light emitting element 100 may be made of group II-VI or group III-V compound semiconductors. The light emitting element 100 may be manufactured on a semiconductor substrate by a separate manufacturing process and disposed on the solder pattern 163 by the transfer process.

The light emitting layer 100a of the light emitting element 100 according to the present embodiment is a structure of a P-N junction structure in which the first conductive semiconductor layer 100-1, the active layer 100-2, and the second conductive semiconductor layer 100-3 are formed sequentially.

In addition, the side surfaces of the lower electrode 214 and the light emitting layer 100a are surrounded by the first and second passivation layers 216 and 220 forming the reflector 16, and the reflective layer 218 is formed to allow the light from the light emitting element 100 to be reflected and emitted externally between the first and second passivation layers 216 and 220.

The pad pattern 230 is formed on the lower surface of the light emitting element 100, and the pad pattern 230 is bonded on the solder pattern 163 formed on the first electrode 161 disposed above the bank pattern 130.

The light emitting element 100 may be formed in an inverted trapezoidal shape with a width increasing from the bottom to a central portion thereof.

The area of the light emitting element 100 may be smaller than or equal to the areas of the bank pattern 130 and the first electrode 161. However, the present disclosure is not necessarily limited thereto.

A width between the left and right side surfaces of the central portion of the light emitting layer 100a of the light emitting element 100 may be greater than a width between the left and right side surfaces of the lower and upper portions thereof.

The width between the left and right side surfaces of the lower portion and the width between the left and right side surfaces of the upper portion of the light emitting element 100 may be smaller than the width between the left and right side surfaces of the central portion thereof.

Portions of the light emitting layer 100a under both sides of the upper electrode 252 of the light emitting element 100 may be exposed. However, the present disclosure is not necessarily limited thereto.

The first and second passivation layers 216 and 220 may be disposed in the form of surrounding the entirety of the side surfaces excluding a portion of the upper portion of the light emitting layer 100a of the light emitting element 100 and the side surfaces and lower surface of the lower electrode 214.

The light emitting element 100 is separated from a growth substrate 210 before being transferred onto the panel and disposed on a carrier substrate 250.

When the active layer 100-2, which is an epi structure, is separated from the growth substrate 210, a laser (laser lift off (LLO)) is radiated to the growth substrate from a laser source, and thus the carrier substrate 250 is made of a material capable of transmitting the laser. For example, the growth substrate 210 may be made of sapphire.

The carrier substrate 250 may be made of polymer resin, glass, quartz, a synthetic resin film, a transparent substrate, and a transparent flexible polymer substrate.

The first conductive semiconductor layer 100-1 forming the light emitting layer 100a is a semiconductor layer in which holes with positive charges move as carriers to generate a current and may be made of a P—GaN-based material. The P—GaN-based material may be GaN, AlGaN, InGaN, AlInGaN, etc., and impurities used for doping the P-type semiconductor layer may include Mg, Zn, Be, etc.

The lower electrode 214 is formed on the first conductive semiconductor layer 100-1 to form an ohmic contact, and the pad pattern 230 is formed on the lower surface of the lower electrode 214. As the light emitting element 100 is transferred onto the panel, the light emitting element 100 may be in contact with a pixel electrode (not shown) to receive a voltage corresponding to a data voltage through a TFT.

The second conductive semiconductor layer 100-3 is a semiconductor layer in which free electrons with negative charges move as carriers to generate a current and may be made of an n-GaN-based material. The n-GaN-based material may be GaN, AlGaN, InGaN, AlInGaN, etc., and impurities used for doping the second conductive semiconductor layer 100-3 may include Si, Ge, Se, Te, C, etc. In addition, in some cases, a buffer layer, such as an undoped GaN-based semiconductor layer, may be additionally formed between the growth substrate 210 and the N-type semiconductor layer.

The active layer 100-2 may be disposed on the first conductive semiconductor layer 100-1 and have an MQW structure that has a well layer and a barrier layer with a higher band gap than the well layer. For example, the active layer 100-2 may have a MQW structure, such as InGaN/GaN.

In addition, the first and second passivation layers 216 and 220 forming the reflector 16 are disposed to surround the lower surfaces and side surfaces of the light emitting layer 100a and the lower electrode 214. Each of the first and second passivation layers 216 and 220 may be formed as a multilayered or single-layer film made of an inorganic material.

The first and second passivation layers 216 and 220 may be used as insulating layers or protective layers.

The first and second passivation layers 216 and 220 may be made of any one selected from the group consisting of SiO2, Si3N4, and a resin or made of an oxide including at least one of Ni, Ti, Pt, Pd, Cu, CuW, Mo, MoW, Ag, and Al.

For example, the inorganic material may be a metal oxide or metal nitride, and specifically, the inorganic material may include at least one of SiO2, SiNx, SiON, Al2O3, TiO2, Ta2O5, HfO2, and ZrO2.

In addition, the reflective layer 218 may be disposed between the first and second passivation layers 216 and 220 and disposed to overlap the lower surfaces and side surfaces of the lower electrode 214 and the light emitting layer 100a. The reflective layer 218 reflects light generated in the light emitting element 100 and emits the reflected light upward from the light emitting element 100.

The reflective layer 218 may be formed as a single or multi metal layer made of one or more among Al, Pt, Pd, Ag, Mg, Au, Ni, Nd, Ir, Cr, Li, Ca, Mo, Ti, W, and Cu. In particular, a metal layer material with a high light reflectance may be preferably used as the material of the reflective layer 218. In the present embodiment, aluminum (Al) is used as the material of the reflective layer 218. However, the present disclosure is not limited thereto.

The lower electrode 214 may be in contact with the first conductive semiconductor layer 100-1 of the light emitting layer 100a, and the upper electrode 252 may be in contact with the second conductive semiconductor layer 100-3.

The lower electrode 214 and the upper electrode 252 may be made of a transparent or translucent electrode material, but are not necessarily limited thereto. The transparent or translucent electrode material may include one or more selected from the group consisting of ITO, IZO, zinc oxide (ZnO), indium oxide (In2O3), indium gallium oxide (IGO), and aluminum zinc oxide (AZO).

In addition, the pad pattern 230 may be formed on the lower surface of the lower electrode 214 to form an ohmic contact.

The pad pattern 230 may be formed in a stacked structure of a first metal layer 230a, a second metal layer 230b, a third metal layer 230c, and a fourth metal layer 230d or a single layer structure formed of a single metal layer that is any one of the above metal layers, but is not necessarily limited thereto.

When the pad pattern 230 has the stacked structure, the second and third metal layers 230b and 230c may be formed between the first metal layer 230a and the fourth metal layer 230d. Although each of the first to fourth metal layers 230a to 230d may be made of any one of Au, Al, and Ni or an alloy thereof, and the first and fourth metal layers 230a and 230d may be made of a different metal from the second and third metal layers 230b and 230c, the present disclosure is not limited thereto. The second metal layer 230b may be made of a different metal from the first, third, and fourth metal layers 230a, 230c, and 230d. For example, the first and fourth metal layers 230a and 230d may contain gold (Au), the second metal layer 230b may contain aluminum (Al), and the third metal layer 230c may contain nickel (Ni).

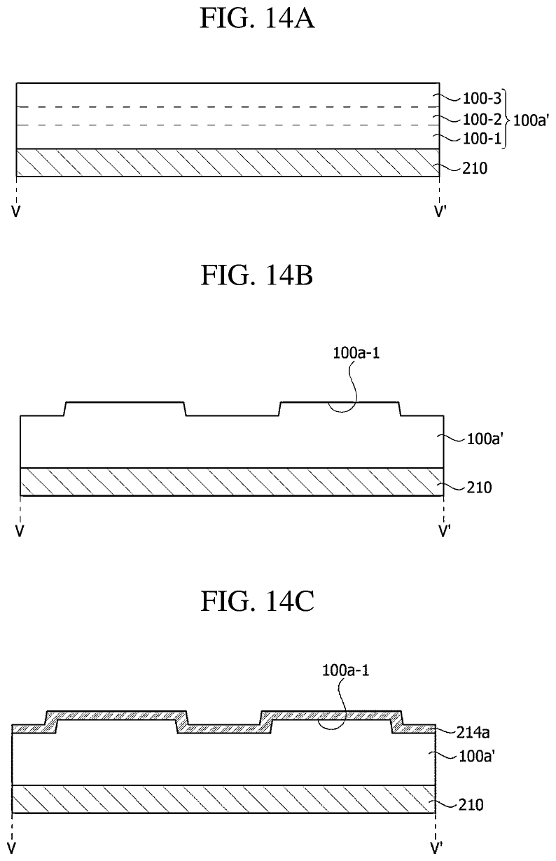

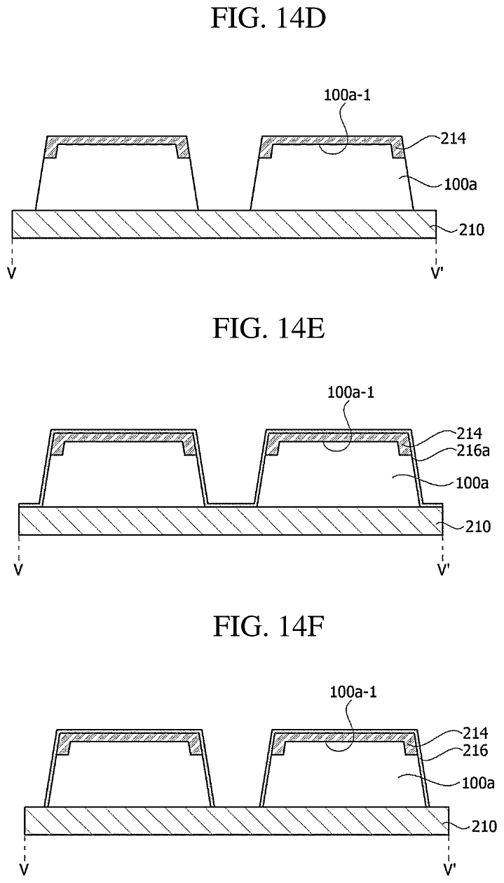

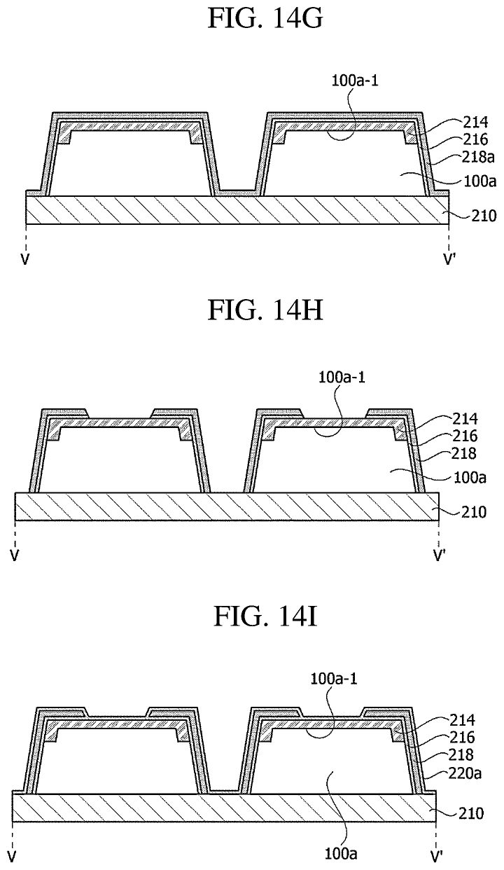

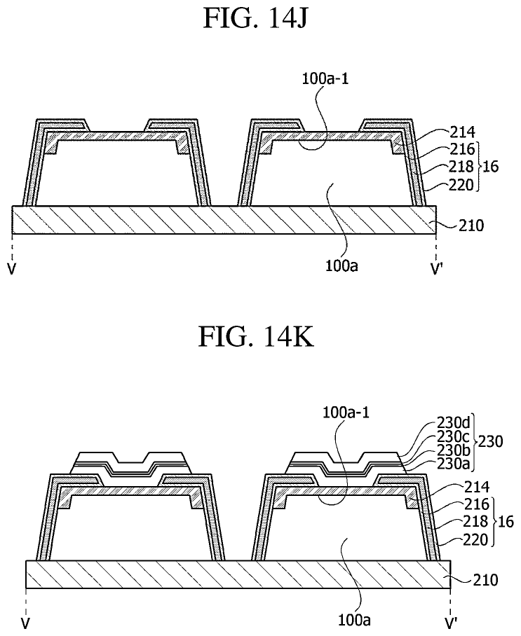

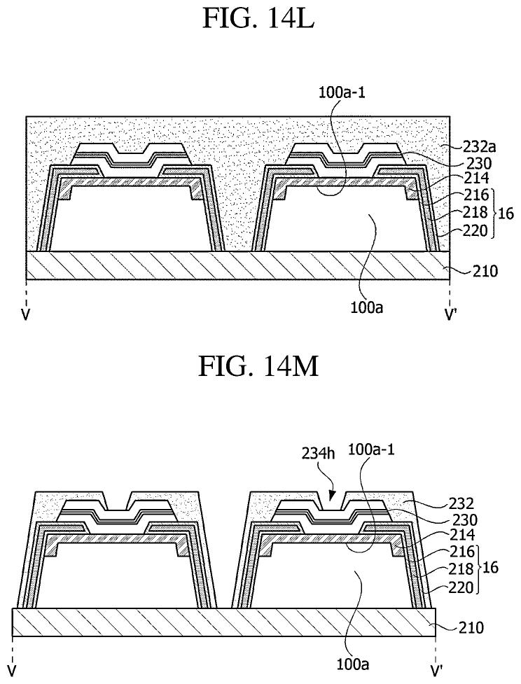

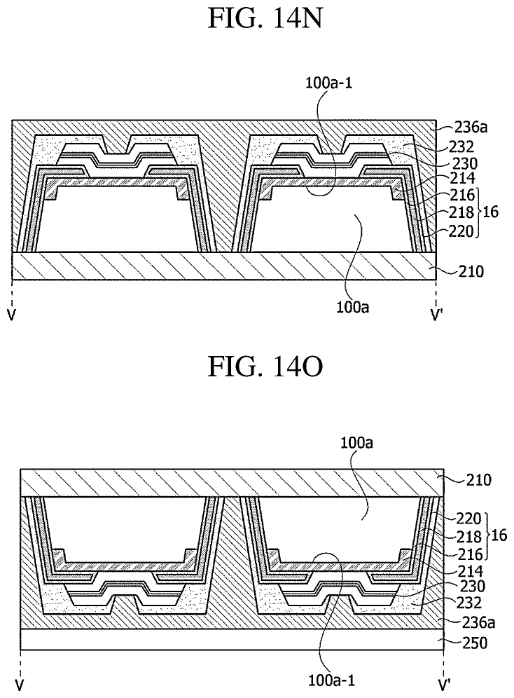

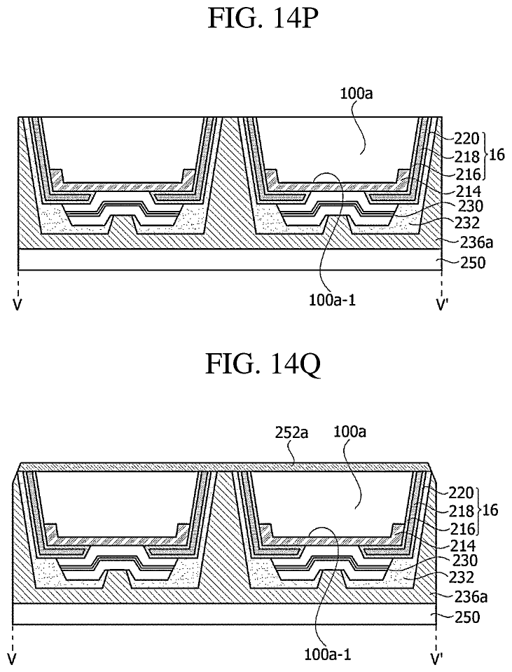

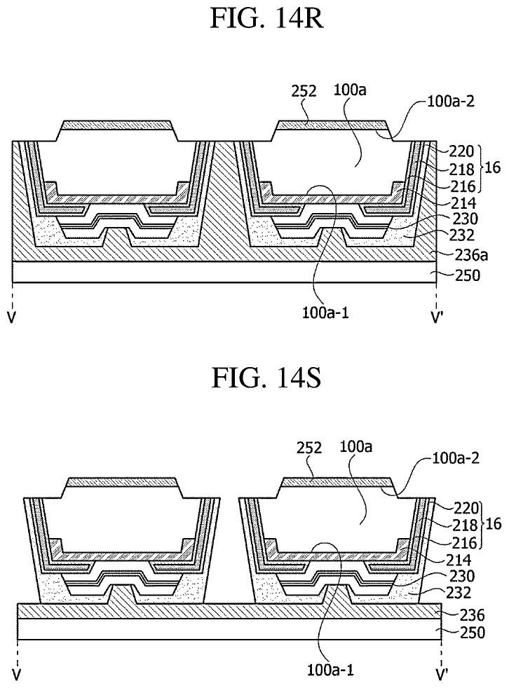

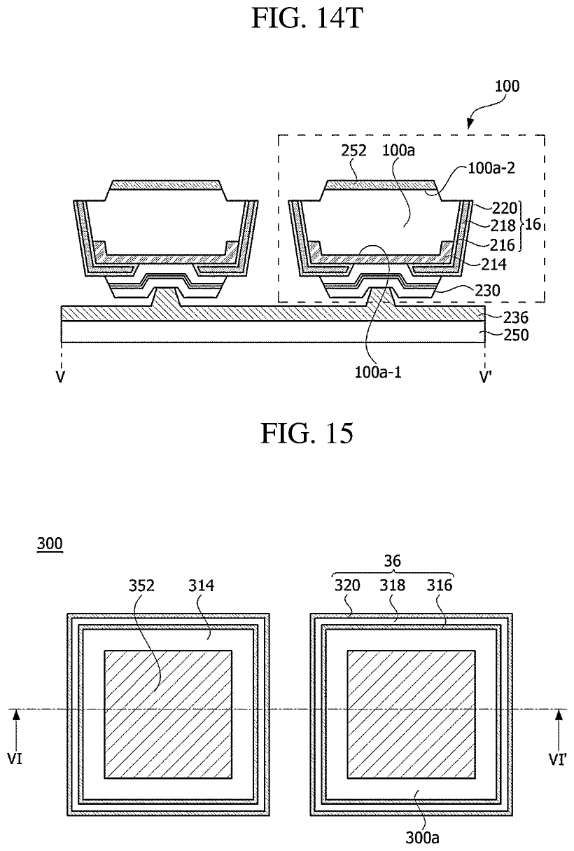

When the light emitting element 100 formed on the growth substrate 210 (see FIG. 14A) is transferred onto the substrate 110 (see FIG. 10) through the carrier substrate 250, the lower electrode 214 is connected to the pixel electrode (not shown) through the pad pattern 230, and thus a positive voltage is applied to the lower electrode 214 in contact with the first conductive semiconductor layer 100-1 through the pixel electrode, and a negative voltage is applied to the upper electrode 252 in contact with the first conductive semiconductor layer 100-1 through the second electrode 170. Therefore, a current flows between the pixel electrode (not shown) and the second electrode 170 by the movement of electrons of the second conductive semiconductor layer 100-3 and the flow of holes of the first conductive semiconductor layer 100-1.

In addition, the light emitting layer 100a emits light by recombination of electrons and holes according to the current flowing between the pixel electrode and the second electrode 170.

Therefore, the light generated in the light emitting element 100 is reflected by the reflective layer 218 disposed in the first and second passivation layers 216 and 220 and emitted upward from the light emitting element 100.

Hereinafter, a process of manufacturing the light emitting element of the display device according to one embodiment of the present specification will be described.

FIGS. 14A to 14T are cross-sectional views showing a process of manufacturing the light emitting element of the display device according to one embodiment of the present specification.

Referring to FIG. 14A, the growth substrate 210 for forming an epi structure of one among RED, GREEN, and BLUE types that form the light emitting element is provided.

The growth substrate 210 may be formed as a conductive or insulating substrate. The growth substrate 210 may be made of at least any one of sapphire, SiC, Si, GaAs, GaN, ZnO, Si, GaP, InP, Ge, and Ga2O3. However, the present disclosure is not necessarily limited thereto.

Next, the first conductive semiconductor layer 100-1, the active layer 100-2, and the second conductive semiconductor layer 100-3 that form a light emitting layer portion 100a′ are sequentially deposited on the growth substrate 210.

The first conductive semiconductor layer 100-1, the active layer 100-2, and the second conductive semiconductor layer 100-3 may be formed using an MOCVD method, a CVD method, a PECVD method, an MBE method, an HVPE method, or an epitaxial method.

The first conductive semiconductor layer 100-1 is a semiconductor layer in which holes with positive charges move as carriers to generate a current.

The first conductive semiconductor layer 100-1 may include a semiconductor material with a composition formula of InxAlyGal-x-yN (0≤x≤1, 0≤x−y≤1, 0≤x+y≤1 selected from GaN, AlN, AlGaN, InGaN, InN, InAlGaN, and AlInN, and doped with a p-type dopant, such as Mg, Zn, Ca, Sr, or Ba.

Alternatively, the first conductive semiconductor layer 100-1 may be made of a P—GaN-based material. The P—GaN-based material may be GaN, AlGaN, InGaN, AlInGaN, etc., and impurities used for doping the P-type semiconductor layer may include Mg, Zn, Be, etc.

The second conductive semiconductor layer 100-3 is a semiconductor layer in which free electrons with negative charges move as carriers to generate a current.

The second conductive semiconductor layer 100-3 may be formed by including, for example, an n-type semiconductor layer. The second conductive semiconductor layer 100-3 may include a semiconductor material with a composition formula of InxAlyGal-x-yN (0≤x≤1, 0≤x−y≤1, 0≤x+y≤1 selected from GaN, AlN, AlGaN, InGaN, InN, InAlGaN, and AlInN, and doped with a n-type dopant, such as Si, Ge, or Sn.

Alternatively, the second conductive semiconductor layer 100-3 may be made of an n-GaN-based material. The n-GaN-based material may be GaN, AlGaN, InGaN, AlInGaN, etc., and impurities used for doping the second conductive semiconductor layer 100-3 may include Si, Ge, Se, Te, C, etc.

In addition, the present embodiment is not limited thereto, and the first conductive semiconductor layer 100-1 may include an n-type semiconductor layer, and the second conductive semiconductor layer 100-3 may include a p-type semiconductor layer.

The active layer 100-2 is an area in which electrons and holes recombine, and as the electrons and the holes recombine, the active layer 100-2 may be transitioned to a lower energy level to generate light having the corresponding wavelength.

The active layer 100-2 may be made of, for example, a semiconductor material with a composition formula of InxAlyGal-x-yN (0x≤1, 0≤y−x≤1, 0≤x+y≤1) and formed in a single quantum well structure or an MQW structure.

In addition, the active layer 100-2 may include a quantum wire structure or a quantum dot structure.

The active layer 100-2 may be disposed on the first conductive semiconductor layer 100-1 and may have an MQW structure that has a well layer and a barrier layer with a higher band gap than the well layer. For example, the active layer 100-2 may have an MQW structure, such as InGaN/GaN.

Subsequently, referring to FIG. 14B, a first flat protrusion 100a-1 is formed by removing a portion of the light emitting layer portion 100a′ in an area excluding an area used as the active layer by selectively patterning the light emitting layer portion 100a′.

Next, referring to FIG. 14C, a lower electrode layer 214a made of a transparent conductive material, such as ITO or IZO, used as an electrode is deposited on the light emitting layer portion 100a′.

The lower electrode layer 214a may be made of a transparent or translucent electrode material, but is not necessarily limited thereto. The transparent or translucent electrode material may include one or more selected from the group consisting of ITO, IZO, ZnO, In₂O₃, IGO, and AZO.

Subsequently, referring to FIG. 14D, by performing a patterning process using a photography process to selectively remove the lower electrode layer 214a and the light emitting layer portion 100a′ disposed thereunder, light emitting element areas are separated, and the lower electrode 214 and the light emitting layer 100a of the light emitting element are formed. In this case, the lower electrode 214 may be formed on the first protrusion 100a-1 of the light emitting layer 100a.

Next, referring to FIG. 14E, a first passivation layer portion 216a is formed on the growth substrate 210 including the lower electrode 214 and the light emitting layer 100a. The first passivation layer portion 216a may be formed as a multilayered or single-layer film made of an inorganic material or an organic material.

The first passivation layer portion 216a may be made of any one selected from the group consisting of SiO2, Si3N4, and a resin or made of an oxide including at least one of Ni, Ti, Pt, Pd, Cu, CuW, Mo, MoW, Ag, and Al.

For example, the inorganic material may be a metal oxide or metal nitride, and specifically, the inorganic material may include at least one of SiO₂, SiNₓ, SiON, Al₂O₃, TiO₂, Ta₂O₅, HfO₂, and ZrO₂.

Subsequently, referring to FIG. 14F, the first passivation layer 216 that limitedly separates each of the light emitting areas is formed by selectively patterning the first passivation layer portion 216a.

The first passivation layer 216 may be disposed on the side surfaces of the light emitting layer 100a and the side surfaces and lower surface of the lower electrode 214.

Subsequently, referring to FIG. 14G, a metal layer 218a used as a reflective mirror is formed on the growth substrate 210 including the first passivation layer 216 formed on the separated light emitting element area.

The metal layer 218a may be formed as a single layer or multiple layers made of one or more among Al, Pt, Pd, Ag, Mg, Au, Ni, Nd, Ir, Cr, Li, Ca, Mo, Ti, W, and Cu. In particular, a material with a high light reflectance may be preferably used as the material of the metal layer 218a. In the present embodiment, an example of a case in which aluminum (Al) is used as the material of the metal layer 218a is described, but the present disclosure is not limited thereto.

Next, referring to FIG. 14H, the reflective layer 218 is formed in each light emitting element area by selectively patterning the metal layer 218a through the photolithography process. When the metal layer 218a is patterned, the portion of the first passivation layer 216 disposed under the metal layer 218a together with the metal layer 218a disposed on the light emitting element area is simultaneously removed, and thus a portion of the lower electrode 214 is also exposed.

Subsequently, referring to FIG. 14I, a second passivation layer portion 220a is formed on the growth substrate 210 including the reflective layer 218 and the exposed portion of the lower electrode 214. The second passivation layer portion 220a may be formed as a multilayered or single-layer film made of an inorganic material.

The second passivation layer portion 220a may be made of any one selected from the group consisting of SiO2, Si3N4, and a resin or made of an oxide including at least one of Ni, Ti, Pt, Pd, Cu, CuW, Mo, MoW, Ag, and Al.

For example, the inorganic material may be a metal oxide or metal nitride, and specifically, the inorganic material may include at least one of SiO2, SiNx, SiON, Al2O3, TiO2, Ta2O5, HfO2, and ZrO2.

When the second passivation layer portion 220a is formed, the second passivation layer portion 220a may be made of a material that is the same as or differs from that of the first passivation layer portion 216a.

Next, referring to FIG. 14J, the second passivation layer 220 that limitedly separates each of the light emitting areas is formed by selectively patterning the second passivation layer portion 220a.

When the second passivation layer portion 220a is patterned, the second passivation layer portion 220a in contact with the lower electrode 214 and a surface of the growth substrate 210 may also be removed.

As described above, the reflector 16 may include the first passivation layer 216, the second passivation layer 220, and the reflective layer 218 disposed there between.

The reflective layer 218 forming the reflector 16 may be disposed in a form surrounded by the first passivation layer 216 and the second passivation layer 220. In addition, the first and second passivation layers 216 and 220 may be disposed in the form of surrounding the side surfaces of the light emitting layer 100a and the side surfaces and upper surface of the lower electrode 214. In addition, the reflective layer 218 may be disposed between the first and second passivation layers 216 and 220 to overlap the side surfaces of the light emitting layer 100a and the side surfaces and upper surface of the lower electrode 214.

Subsequently, referring to FIG. 14K, the pad pattern 230 in contact with the lower electrode 214 is formed by depositing the metal material layer on the entire surface of the growth substrate 210 including the exposed portion of the lower electrode 214 and the second passivation layer 220 and selectively patterning the metal material layer.

The pad pattern 230 may be formed in a stacked structure of the first metal layer 230a, the second metal layer 230b, the third metal layer 230c, and the fourth metal layer 230d or a single layer structure formed of a single metal layer that is any one of the above metal layers, but is not necessarily limited thereto.

When the pad pattern 230 has the stacked structure, the second and third metal layers 230b and 230c may be interposed between the first metal layer 230a and the fourth metal layer 230d. Although each of the first to fourth metal layers 230a to 230d may be made of any one of Au, Al, and Ni or an alloy thereof, and the first and fourth metal layers 230a and 230d may be made of a different metal from the second and third metal layers 230b and 230c, the present disclosure is not limited thereto. The second metal layer 230b may be made of a different metal from the first, third, and fourth metal layers 230a, 230c, and 230d. For example, the first and fourth metal layers 230a and 230d may contain gold (Au), the second metal layer 230b may contain aluminum (Al), and the third metal layer 230c may contain nickel (Ni).

Next, referring to FIG. 14L, a sacrificial layer 232a is formed on the entire surface of the overall structure of the growth substrate 210 including the pad pattern 230. As the sacrificial layer 232a, any one of insulating materials including SiO2, SiN, and the like may be used selectively.

Subsequently, referring to FIG. 14M, the light emitting element area is separated by selectively patterning the sacrificial layer 232a through the mask process, and at the same time, a contact hole 234h that exposes a portion of the pad pattern 230 is formed.

Next, referring to FIG. 14N, the process of manufacturing the light emitting element on the growth substrate 210 is finished by forming a dummy insulating layer 236a on the entire surface of the growth substrate 210 including the remaining sacrificial layers 232 to planarize the growth substrate 210. A material of the dummy insulating layer 236a may be selected from benzocyclobutene (BCB) or other insulating materials.

Hereinafter, a process of arranging and bonding the light emitting element on the carrier substrate will be described.

The carrier substrate 250 is provided, and a substrate separation process of separating the light emitting element from the growth substrate 210 is performed to transfer the light emitting element onto the carrier substrate 250.

The carrier substrate 250 may be made of polymer resin, glass, quartz, a synthetic resin film, a transparent substrate, and a transparent flexible polymer substrate.

Referring to FIG. 14O, a structure formed on the growth substrate 210 is disposed and bonded on the carrier substrate 250. Although not shown in the drawing, to laminate the growth substrate 210 in an inverted state on the carrier substrate 250, an ultraviolet-reactive resin layer (not shown) that may be used as an adhesive layer may be formed on the carrier substrate 250.

In this case, in the state of inverting the growth substrate 210, a portion of the dummy insulating layer 236a is disposed and bonded on the carrier substrate 250 and exposes the growth substrate 210 externally.

Next, referring to FIG. 14P, after the light emitting element portion of the growth substrate 210 is in contact with the ultraviolet-reactive resin layer (not shown) of the carrier substrate 250, a laser is radiated to a boundary between the light emitting element portion and the growth substrate 210.

The laser radiated after passing through the growth substrate 210 from the laser source may separate the light emitting element portion from the growth substrate 210. In this case, the light emitting element portion may maintain a state of being in contact with the ultraviolet ray-reactive resin layer (not shown) of the carrier substrate 250.

Subsequently, referring to FIG. 14Q, after the growth substrate 210 is removed through laser radiation, an upper electrode layer 252a is formed on the first and second passivation layers 216 and 220 including the light emitting layer 100a, which is the exposed area of the light emitting element portion, the reflective layer 218 disposed between the first and second passivation layers 216 and 220, the sacrificial layer 232, and the dummy insulating layer 236a.

The upper electrode layer 252a may be made of a transparent or translucent electrode material, but is not necessarily limited thereto. The transparent or translucent electrode material may include one or more selected from the group consisting of ITO, IZO, ZnO, In2O3, IGO, and AZO. In the present disclosure, an example of a case in which ITO is used as the transparent electrode material will be described.

Next, referring to FIG. 14R, the upper electrode 252 is formed on the light emitting layer 100a by selectively patterning the upper electrode layer 252a through a mask process. In this case, when the upper electrode layer 252a is patterned, upper portions of the first and second passivation layers 216 and 220 including the side surfaces of the light emitting layer 100a as well as the upper electrode layer 252a, an upper area of the reflective layer 218 disposed between the first and second passivation layers 216 and 220, and upper areas of portions of the sacrificial layer 232 and the dummy insulating layer 236a may be etched together.

The second flat protrusion 100a-2 may be formed on the upper surface of the light emitting layer 100a, and stepped portions (not shown) may be formed on the side surfaces of the light emitting layer 100a.

As described above, the light emitting layer 100a, the lower electrode 214, the upper electrode 252, and the reflective layer 218 disposed between the first and second passivation layers 216 and 220 that surround the side surfaces and lower surfaces of the light emitting layer 100a and the lower electrode 214, which form the light emitting element 100 (see FIG. 14T), are formed.

Subsequently, referring to FIG. 14S, among the externally exposed areas, the dummy insulating layer 236a disposed between the sacrificial layers 232 is selectively removed by performing a dry etching process.

Next, referring to FIG. 14T, the light emitting element 100 remains on the carrier substrate 250 by removing the remaining sacrificial layers 232 through a wet etching process.

As described above, the process of separating the light emitting element 100 according to one embodiment of the present disclosure from the growth substrate 210 and bonding the light emitting element 100 on the carrier substrate 250 is finished.

Meanwhile, hereinafter, a light emitting element of a display device according to another embodiment of the present specification will be described.

FIG. 15 is a plan view showing a light emitting element of a display device according to another embodiment of the present specification.

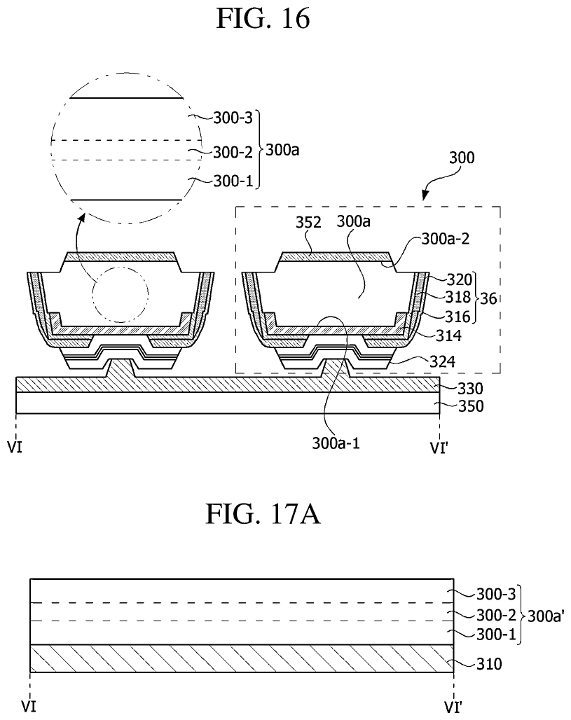

FIG. 16 is a cross-sectional view showing a longitudinal cross-sectional structure of a portion of the light emitting element along line VI-VI′ in FIG. 15 according to one embodiment.

Referring to FIGS. 15 and 16, a light emitting element 300 according to another embodiment of the present specification may be transferred and disposed on the bank pattern (not shown, 130 in FIG. 10) disposed on the substrate (not shown, 110 in FIG. 10) to overlap the bank pattern 130.

In addition, the light emitting element 300 may be in contact with the first electrode (not shown, 161 in FIG. 10) disposed on the bank pattern 130 to overlap the first electrode 161.

An area of the light emitting element 300 may be smaller than or equal to areas of the bank pattern 130 and the first electrode 161. However the present disclosure is not necessarily limited thereto. In addition, for a process margin, the area of the first electrode 161 may be preferably greater than the area of the light emitting element 300.

As shown in FIG. 15, the light emitting element 300 may include a light emitting layer 300a including a first conductive semiconductor layer 300-1, a second conductive semiconductor layer 300-3, and an active layer 300-2 interposed there between, a lower electrode 314 in contact with the first conductive semiconductor layer 300-1 of the light emitting layer 300a, an upper electrode 352 in contact with the second conductive semiconductor layer 300-3 of the light emitting layer 300a, and a reflector 36 covering the side surfaces and lower surfaces of the light emitting layer 300a and the lower electrode 314.

The reflector 36 may include first and second passivation layers 316 and 320 that surround the light emitting layer 300a and the lower electrode 314, and a reflective layer 318 disposed there between.

The first and second passivation layers 316 and 320 may be used as insulating layers or protective layers.

The lower electrode 314 in contact with the first conductive semiconductor layer 300-1 may include an anode, and the upper electrode 352 in contact with the second conductive semiconductor layer 300-3 may include a cathode.

The light emitting layer 300a may include one or more quantum well layers. The doped first and second conductive semiconductor layers 300-1 and 300-3 and the active layer 300-2 of the light emitting element 300 may be made of group II-VI or group III-V compound semiconductors. The light emitting element 300 may be manufactured on a semiconductor substrate by a separate manufacturing process and disposed on a solder pattern (not shown, 162 in FIG. 10) by the transfer process.

The light emitting element 300 may include a lower surface of the light emitting layer 300a on which the lower electrode 314 is disposed, an upper surface of the light emitting layer 300a on which the upper electrode 352 is disposed, and side surfaces or edge portions of the light emitting layer 300a between the lower and upper surfaces thereof.

The lower surface of the light emitting layer 300a may include a first flat protrusion 300a-1 on which the lower electrode 314 is disposed. The upper surface of the light emitting layer 300a may include a second flat protrusion 300a-2 on which the upper electrode 352 is disposed. The first and second flat protrusions 300a-1 and 300a-2 may include stepped portions (not shown) formed on side surfaces thereof.

The stepped portions have smaller heights than the first and second flat protrusions 300a-1 and 300a-2, and the reflector 312 may be disposed on at least a portion of side surfaces of the light emitting element 300 under the stepped portions.

The lower electrode 314 in contact with the first conductive semiconductor layer 300-1 may include an anode, and the upper electrode 352 in contact with the second conductive semiconductor layer 300-2 may include a cathode. The light emitting layer 300a may include one or more quantum well layers. The doped first and second conductive semiconductor layers 300-1 and 300-3 and the active layer 300-2 of the light emitting element 300 may be made of group II-VI or group III-V compound semiconductors. The light emitting element 300 may be manufactured on a semiconductor substrate by a separate manufacturing process and disposed on the solder pattern 163 (see FIG. 10) by the transfer process.

The light emitting layer 300a of the light emitting element 300 according to another embodiment of the present disclosure is a structure of a P-N junction structure in which the first conductive semiconductor layer 300-1, the active layer 300-2, and the second conductive semiconductor layer 300-3 are formed sequentially.

In addition, outer surfaces of the lower electrode 314 and the light emitting layer 300a are surrounded by the first and second passivation layers 316 and 320, and the reflective layer 318 is formed to allow the light from the light emitting element 300 to be reflected and emitted externally between the first and second passivation layers 316 and 320.

A pad pattern 324 is formed on the lower surface of the light emitting element 300, and the pad pattern 324 is bonded on the solder pattern 163 formed on the first electrode 161 disposed above the bank pattern (not shown, 130 in FIG. 10).

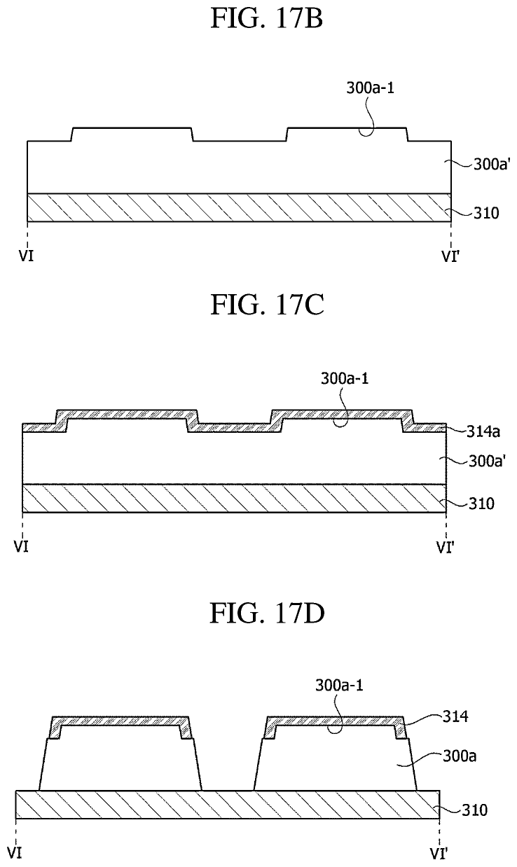

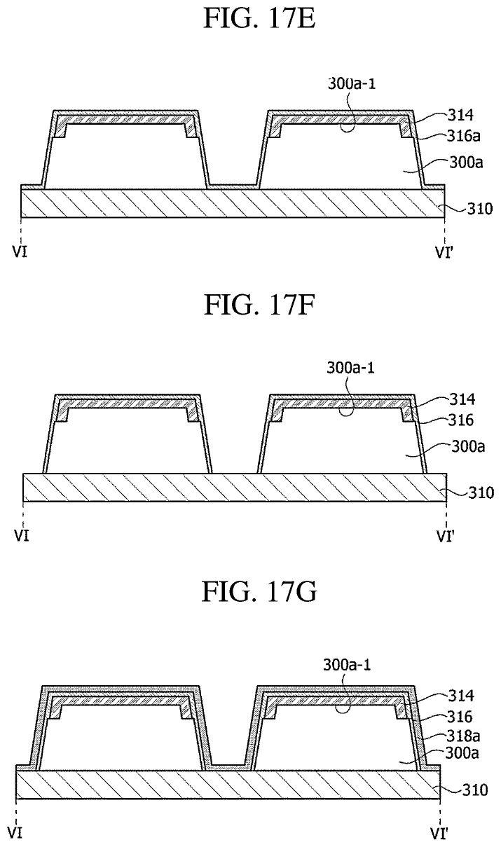

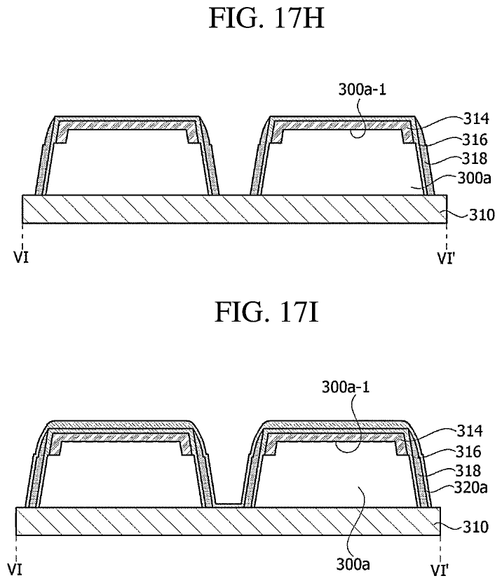

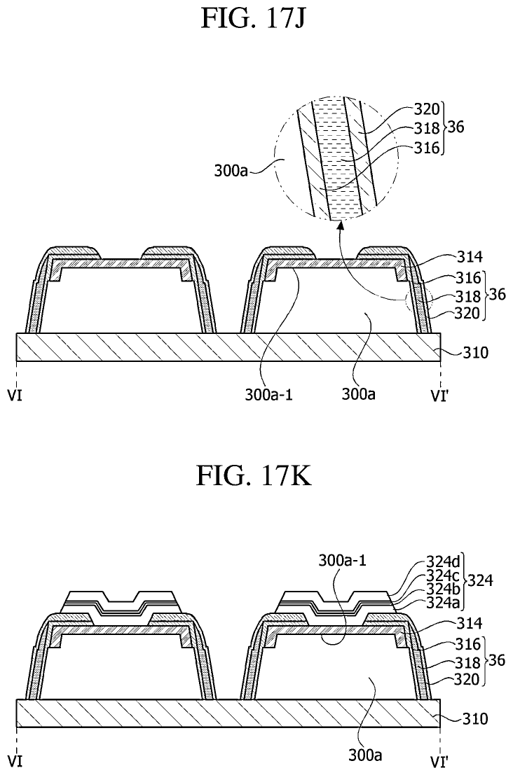

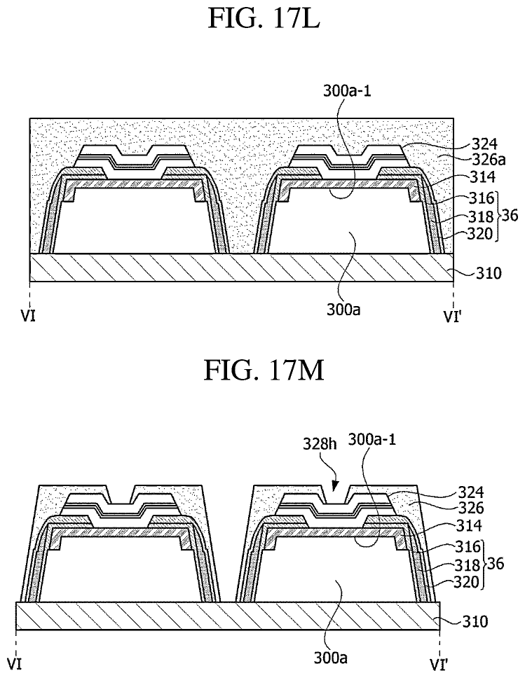

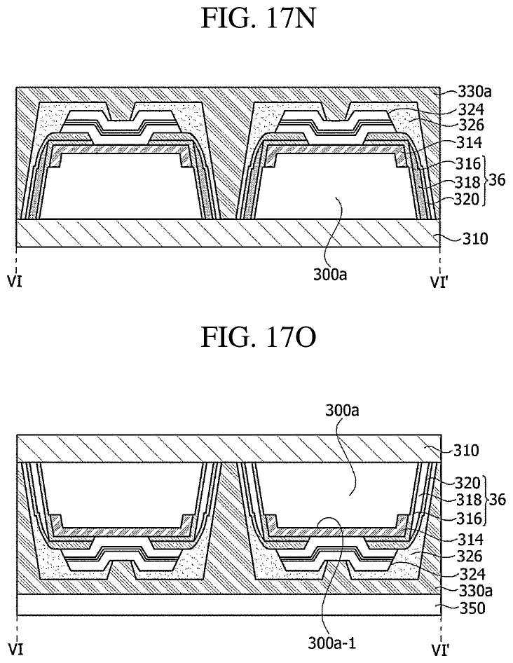

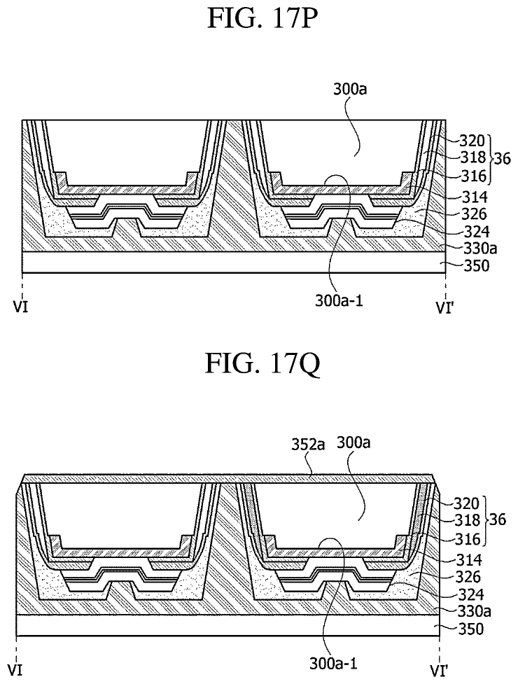

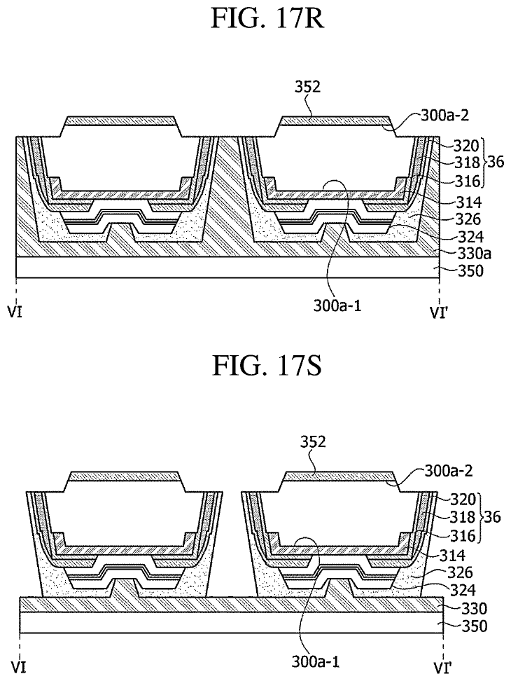

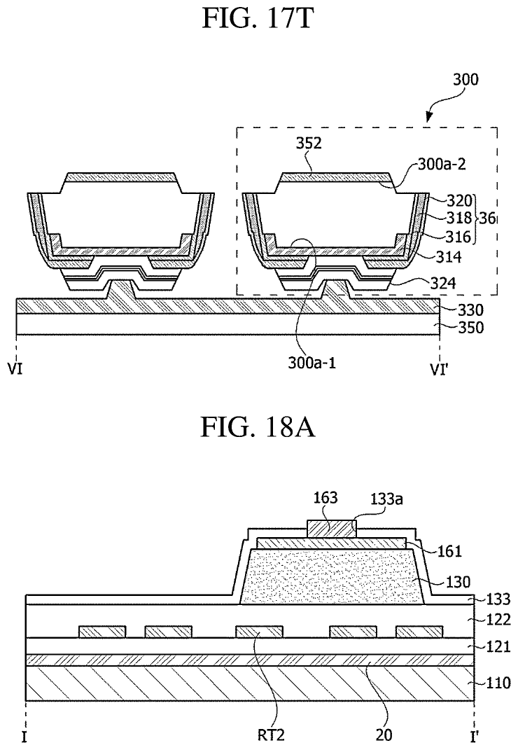

As shown in FIG. 17K, which will described below, the pad pattern 324 may be formed in a stacked structure of a first metal layer 324a, a second metal layer 324b, a third metal layer 324c, and the fourth metal layer 324d or a single layer structure formed of a single metal layer that is any one of the above metal layers, but is not necessarily limited thereto.

When the pad pattern 324 has the stacked structure, the second and third metal layers 324b and 324c may be formed between the first metal layer 324a and the fourth metal layer 324d. Although each of the first to fourth metal layers 324a to 324d may be made of any one of gold (Au), aluminum (Al), and nickel (Ni) or an alloy thereof and the first and fourth metal layers 324a and 324d may be made of a different metal from the second and third metal layers 324b and 324c, the present disclosure is not limited thereto. The second metal layer 324b may be made of a different metal from the first, third, and fourth metal layers 324a, 324c, and 324d. For example, the first and fourth metal layers 324a and 324d may contain gold (Au), the second metal layer 324b may contain aluminum (Al), and the third metal layer 324c may contain nickel (Ni).

The light emitting element 300 is separated from a growth substrate 310 before being transferred onto the panel, and disposed on a carrier substrate 350.

When the light emitting layer 300a, which is an epi structure, is separated from the growth substrate 310, a laser (laser lift off (LLO)) is radiated to the growth substrate from the laser source, and thus the carrier substrate 350 is made of a material capable of transmitting the laser. For example, the growth substrate 310 may be made of sapphire.

The carrier substrate 350 may be made of polymer resin, glass, quartz, a synthetic resin film, a transparent substrate, and a transparent flexible polymer substrate.

The first conductive semiconductor layer 300-1 forming the light emitting layer 300a is a semiconductor layer in which holes with positive charges move as carriers to generate a current and may be made of a P—GaN-based material. The P—GaN-based material may be GaN, AlGaN, InGaN, AlInGaN, etc., and impurities used for doping the P-type semiconductor layer may include Mg, Zn, Be, etc.

The pad pattern 324 is formed on the first conductive semiconductor layer 300-1 to form an ohmic contact. As the light emitting element 300 is transferred onto the panel, the light emitting element 100 may be in contact with a pixel electrode (not shown) to receive a voltage corresponding to a data voltage through a TFT.

The second conductive semiconductor layer 300-3 is a semiconductor layer in which free electrons with negative charges move as carriers to generate a current and may be made of an n-GaN-based material. The n-GaN-based material may be GaN, AlGaN, InGaN, AlInGaN, etc., and impurities used for doping the n-type semiconductor layer 212c may include Si, Ge, Se, Te, C, etc. In addition, in some cases, a buffer layer, such as an undoped GaN-based semiconductor layer, may be additionally formed between the growth substrate 210 and the N-type semiconductor layer.

The active layer 300-2 may be disposed on the first conductive semiconductor layer 300-1 and may have an MQW structure that has a well layer and a barrier layer with a higher band gap than the well layer. For example, the active layer 300-2 may have a MQW structure, such as InGaN/GaN.

In addition, the first and second passivation layers 316 and 320 are disposed to surround the lower surfaces and side surfaces of the light emitting layer 300a and the lower electrode 314. Each of the first and second passivation layers 316 and 320 may be formed as a multilayered or single-layer film made of an inorganic material.

The first and second passivation layers 316 and 320 may be made of any one selected from the group consisting of SiO2, Si3N4, and a resin or made of an oxide including at least one of Ni, Ti, Pt, Pd, Cu, CuW, Mo, MoW, Ag, and Al.

The inorganic material may be a metal oxide or metal nitride, and specifically, the inorganic material may include at least one of SiO2, SiNx, SiON, Al2O3, TiO2, Ta2O5, HfO2, and ZrO2.

In addition, the reflective layer 318 may be disposed between the first and second passivation layers 316 and 320 and disposed to overlap the lower surfaces and side surfaces of the lower electrode 314 and the light emitting layer 300a. The reflective layer 318 reflects light generated in the light emitting element 300 and emits the reflected light upward from the light emitting element 300.

The reflective layer 318 may be formed as a single or multilayered metal layer made of one or more among Al, Pt, Pd, Ag, Mg, Au, Ni, Nd, Ir, Cr, Li, Ca, Mo, Ti, W, and Cu. In particular, a material with a high light reflectance may be preferably used as the material of the reflective layer 318. In the present embodiment, aluminum (Al) is used as the material of the reflective layer 318.

The lower electrode 314 may be in contact with the first conductive semiconductor layer 300-1 of the light emitting layer 300a, and the upper electrode 352 may be in contact with the second conductive semiconductor layer 300-3.

The lower electrode 314 and the upper electrode 352 may be made of a transparent or translucent electrode material, but are not necessarily limited thereto. The transparent or translucent electrode material may include one or more selected from the group consisting of ITO, IZO, ZnO, In2O3, IGO, and AZO

In addition, the pad pattern 330 may be formed on the lower surface of the lower electrode 314 to form an ohmic contact.

When the light emitting element 300 formed on the growth substrate 310 (see FIG. 17A) is transferred onto the panel substrate (not shown, 110 in FIG. 10) through the carrier substrate 350, the lower electrode 314 is connected to the pixel electrode (not shown) through the pad pattern 324, and thus a positive voltage is applied to the lower electrode 314 in contact with the first conductive semiconductor layer 300-1 through the pixel electrode, and a negative voltage is applied to the upper electrode 352 in contact with the second conductive semiconductor layer 300-3 through the second electrode 170 (see FIG. 10). Therefore, a current flows between the pixel electrode (not shown) and the second electrode (not shown, 170 in FIG. 10) by the movement of electrons of the second conductive semiconductor layer 300-3 and the flow of holes of the first conductive semiconductor layer 300-1.

In addition, the light emitting layer 300a emits light by recombination of electrons and holes according to the current flowing between the pixel electrode and the second electrode 170.

Therefore, the light generated in the light emitting element 300 is reflected by the reflective layer 318 disposed in the first and second passivation layers 316 and 320 and emitted upward from the light emitting element 300.

Hereinafter, a process of manufacturing the light emitting element of the display device according to another embodiment of the present specification will be described.

FIGS. 17A to 17T are cross-sectional views showing a process of manufacturing the light emitting element of the display device according to another embodiment of the present specification.

Referring to FIG. 17A, there is provided the growth substrate 310 for forming an epi structure of one among RED, GREEN, and BLUE types that form the light emitting element.

The growth substrate 310 may be formed as a conductive or insulating substrate. For example, the growth substrate 310 may be made of at least any one of sapphire, SiC, Si, GaAs, GaN, ZnO, Si, GaP, InP, Ge, and Ga2O3. However, the present disclosure is not necessarily limited thereto.

Next, the first conductive semiconductor layer 300-1, the active layer 300-2, and the second conductive semiconductor layer 300-3 that form a light emitting layer portion 300a′ are sequentially deposited on the growth substrate 310.

The first conductive semiconductor layer 300-1, the active layer 300-2, and the second conductive semiconductor layer 300-3 may be formed using an MOCVD method, a CVD method, a PECVD method, an MBE method, an HVPE method, or an epitaxial method.

The first conductive semiconductor layer 300-1 is a semiconductor layer in which holes with positive charges move as carriers to generate a current.

The first conductive semiconductor layer 300-1 may include a semiconductor material with a composition formula of InxAlyGal-x-yN (0≤x≤1, 0≤x-y≤1, 0≤x+y≤1 selected from GaN, AlN, AlGaN, InGaN, InN, InAlGaN, and AlInN, and doped with a p-type dopant, such as Mg, Zn, Ca, Sr, or Ba.

Alternatively, the first conductive semiconductor layer 300-1 may be made of a P—GaN-based material. The P—GaN-based material may be GaN, AlGaN, InGaN, AlInGaN, etc., and impurities used for doping the P-type semiconductor layer may include Mg, Zn, Be, etc.

The second conductive semiconductor layer 300-3 is a semiconductor layer in which free electrons with negative charges move as carriers to generate a current.

The second conductive semiconductor layer 300-3 may be formed by including, for example, an n-type semiconductor layer. The second conductive semiconductor layer 300-3 may include a semiconductor material with a composition formula of InxAlyGal-x-yN (0≤x≤1, 0≤x−y≤1, 0≤x+y≤1 selected from GaN, AlN, AlGaN, InGaN, InN, InAlGaN, and AlInN, and doped with a n-type dopant, such as Si, Ge, or Sn.

Alternatively, the second conductive semiconductor layer 300-3 may be made of an n-GaN-based material. The n-GaN-based material may be GaN, AlGaN, InGaN, AlInGaN, etc., and impurities used for doping the n-type semiconductor layer 212c may include Si, Ge, Se, Te, C, etc.

In addition, the present embodiment is not limited thereto, and the first conductive semiconductor layer 300-1 may include an n-type semiconductor layer, and the second conductive semiconductor layer 300-3 may include a p-type semiconductor layer.

The active layer 300-2 is an area in which electrons and holes recombine, and as the electrons and the holes recombine, the active layer 100-2 may be transitioned to a lower energy level to generate light having the corresponding wavelength.

The active layer 300-2 may be made of, for example, a semiconductor material with a composition formula InxAlyGal-x-yN (0x≤1, 0≤y−x≤1, 0≤x+y≤1) and formed in a single quantum well structure or an MQW structure.

In addition, the active layer 300-2 may include a quantum wire structure or a quantum dot structure.

The active layer 300-2 may be disposed on the first conductive semiconductor layer 300-1 and may have an MQW structure that has a well layer and a barrier layer with a higher band gap than the well layer. For example, the active layer 300-2 may have a MQW structure, such as InGaN/GaN.

Subsequently, referring to FIG. 17B, an area in which a first protrusion is formed is limited by selectively patterning the light emitting layer portion 300a′ and removing a portion of the light emitting layer portion 300a′ in an area excluding an area used as the active layer.

Next, referring to FIG. 17C, a first electrode layer 314a made of a transparent conductive material, such as ITO or IZO, used as a first electrode, is deposited on the light emitting layer portion 300a′.

The first electrode layer 314a may be made of a transparent or translucent electrode material, but is not necessarily limited thereto. The transparent or translucent electrode material may include one or more selected from the group consisting of ITO, IZO, ZnO, In2O3, IGO, and AZO.

Subsequently, referring to FIG. 17D, by performing a patterning process using a mask process to selectively remove the first electrode layer 314a and the light emitting layer portion 300a′ disposed under the first electrode layer 314a, light emitting element areas are separated, and the lower electrode 314 and the light emitting layer 300a of the light emitting element are formed.

When the light emitting layer 300a is formed, the first flat protrusion 300a-1 may also be simultaneously formed on the lower surface of the light emitting layer 300a.

Next, referring to FIG. 17E, a first passivation layer portion 316a is formed on the growth substrate 310 including the lower electrode 314 and the light emitting layer 300a. The first passivation layer portion 316a may be formed as a multilayered or single-layer film made of an inorganic material.

The first passivation layer portion 316a may be made of any one selected from the group consisting of SiO2, Si3N4, and a resin or made of an oxide including at least one of Ni, Ti, Pt, Pd, Cu, CuW, Mo, MoW, Ag, and Al.

For example, the inorganic material may be a metal oxide or metal nitride, and specifically, the inorganic material may include at least one of SiO2, SiNx, SiON, Al2O3, TiO2, Ta2O5, HfO2, and ZrO2.

Subsequently, referring to FIG. 17F, the first passivation layer 316 that limitedly separates each of the light emitting areas is formed by selectively patterning the first passivation layer portion 316a.

The first passivation layer 316 may be disposed on the side surfaces of the light emitting layer 300a and the side surfaces and lower surface of the lower electrode 314.

Subsequently, referring to FIG. 17G, a metal layer 318a used as a reflective mirror is formed on the entire surface of the growth substrate 210 including the first passivation layer 316 formed on the separated light emitting element area.

The metal layer 318a may be formed as a single-layer or multiple layers made of one or more among Al, Pt, Pd, Ag, Mg, Au, Ni, Nd, Ir, Cr, Li, Ca, Mo, Ti, W, and Cu. In particular, a material with a high light reflectance may be preferably used as the material of the metal layer 318a. In the present embodiment, an example of a case in which aluminum (Al) is used as the material of the metal layer 318a is described, but the present disclosure is not limited thereto.

Next, referring to FIG. 17H, the reflective layer 318 is formed on the side surfaces of the first passivation layer 316 by selectively etching the metal layer 318a through an etch back process.

Subsequently, referring to FIG. 17I, a second passivation layer portion 320a is formed on the growth substrate 310 including the reflective layer 318 and the first passivation layer 316. The second passivation layer portion 320a may be formed as a multilayered or single-layer film made of an inorganic material.

The second passivation layer portion 320a may be made of any one selected from the group consisting of SiO2, Si3N4, and a resin or made of an oxide including at least one of Ni, Ti, Pt, Pd, Cu, CuW, Mo, MoW, Ag, and Al.

For example, the inorganic material may be a metal oxide or metal nitride, and specifically, the inorganic material may include at least one of SiO2, SiNx, SiON, Al2O3, TiO2, Ta2O5, HfO2, and ZrO2.

When the second passivation layer portion 320a is formed, the second passivation layer portion 320a may be made of a material that is the same as or differs from that of the first passivation layer portion 316a.

Next, referring to FIG. 17J, the second passivation layer 320 that limitedly separates each of the light emitting areas is formed by selectively patterning the second passivation layer portion 320a.

When the second passivation layer portion 320a is patterned, the second passivation layer portion 320a in contact with the lower electrode 314 and a surface of the growth substrate 310 may also be removed together to allow portions of the lower electrode 314 and the growth substrate 310 to be exposed to the outside.

The reflective layer 318 may be disposed in a form surrounded by the first passivation layer 316 and the second passivation layer 320. In addition, the first and second passivation layers 316 and 320 may be disposed in the form of surrounding the side surfaces of the light emitting layer 300a and the side surfaces and upper surface of the lower electrode 314. In addition, the reflective layer 318 may be disposed between the first and second passivation layers 316 and 320 and disposed to overlap the side surfaces of the light emitting layer 300a.

The reflector 16 may include first and second passivation layers 316 and 320 that surround the light emitting layer 300a and the lower electrode 314, and the reflective layer 318 disposed therebetween.

Subsequently, referring to FIG. 17K, the pad pattern 324 in contact with the lower electrode 314 is formed by depositing the metal material layer on the entire surface of the growth substrate 310 including the exposed portion of the lower electrode 314 and the second passivation layer 320 and selectively patterning the metal material layer.

As shown in FIG. 17K, the pad pattern 324 may be formed in a stacked structure of the first metal layer 324a, the second metal layer 324b, the third metal layer 324c, and the fourth metal layer 324d or a single layer structure formed of a single metal layer that is any one of the above metal layers, but is not necessarily limited thereto.

When the pad pattern 324 has the stacked structure, the second and third metal layers 324b and 324c may be interposed between the first metal layer 324a and the fourth metal layer 324d. Although each of the first to fourth metal layers 324a to 324d may be made of any one of gold (Au), aluminum (Al), and nickel (Ni) or an alloy thereof, and the first and fourth metal layers 324a and 324d may be made of a different metal from the second and third metal layers 324b and 324c, the present disclosure is not limited thereto. The second metal layer 324b may be made of a different metal from the first, third, and fourth metal layers 324a, 324c, and 324d. For example, the first and fourth metal layers 324a and 324d may contain gold (Au), the second metal layer 324b may contain aluminum (Al), and the third metal layer 324c may contain nickel (Ni).

Next, referring to FIG. 17L, a sacrificial layer 326a is formed on the overall structure of the growth substrate 310 including the pad pattern 324. As the sacrificial layer 326a, any one of insulating materials including SiO2, SiN, etc., may be used selectively.

Subsequently, referring to FIG. 17M, the light emitting element area is separated by selectively patterning the sacrificial layer 232a through the mask process, and at the same time, a contact hole 328h that exposes a portion of the pad pattern 324 is formed.

Next, referring to FIG. 17N, the process of manufacturing the light emitting element on the growth substrate 310 is finished by forming a dummy insulating layer 330a on the growth substrate 310 including the sacrificial layer 326 to planarize the growth substrate 310. As a material of the dummy insulating layer 330a, BCB or other insulating materials may be used selectively.

Hereinafter, a process of arranging and bonding the light emitting element portion on the carrier substrate will be described.

First, the carrier substrate 350 is provided, and a substrate separation process of separating the light emitting element from the growth substrate 310 is performed to transfer the light emitting element onto the carrier substrate 350.

The carrier substrate 350 may be made of polymer resin, glass, quartz, a synthetic resin film, a transparent substrate, and a transparent flexible polymer substrate.

Referring to FIG. 17O, a structure formed on the growth substrate 310 is disposed and bonded on the carrier substrate 350. Although not shown in the drawing, to laminate the growth substrate 310 in an inverted state on the carrier substrate 350, an ultraviolet-reactive resin layer (not shown) that may be used as an adhesive layer may be formed on the carrier substrate 350.

In this case, in the state of inverting the growth substrate 310, a portion of the dummy insulating layer 330a is disposed and bonded on the carrier substrate 350 to expose the growth substrate 310 to the outside.

Next, referring to FIG. 17P, after the light emitting element portion of the growth substrate 310 is in contact with the ultraviolet-reactive resin layer (not shown) of the carrier substrate 350, a laser is radiated to a boundary between the light emitting element portion and the growth substrate 310.

The laser radiated after passing through the growth substrate 310 from the laser source may separate the light emitting element portion from the growth substrate 310. In this case, the light emitting element portion may maintain a state of being in contact with the ultraviolet ray-reactive resin layer (not shown) of the carrier substrate 350.

Subsequently, referring to FIG. 17Q, after the growth substrate 310 is removed through laser radiation, a second electrode layer 352a is formed on the first and second passivation layers 316 and 320 including the light emitting layer 300a, which is the exposed area of the light emitting element portion, the area of the reflective layer 318 interposed between the first and second passivation layers 316 and 320, the sacrificial layer 326, and the dummy insulating layer 330a.

The second electrode layer 352a may be made of a transparent or translucent electrode material, but is not necessarily limited thereto. The transparent or translucent electrode material may include one or more selected from the group consisting of ITO, IZO, ZnO, In2O3, IGO, and AZO. In the present disclosure, an example of a case in which ITO is used as the transparent electrode material will be described.

Next, referring to FIG. 17R, a second electrode 352 is formed on the light emitting layer 300a by selectively patterning the second electrode layer 352a through the mask process. In this case, when the second electrode layer 352a is patterned, upper portions of the first and second passivation layers 316 and 320 including the side surfaces of the light emitting layer 300a as well as the second electrode layer 352a, an upper area of the reflective layer 318 disposed between the first and second passivation layers 316 and 320, and upper areas of portions of the sacrificial layer 326 and the insulating layer 330a may be etched together and exposed to the outside.

In this case, the second flat protrusion 300a-2 may be formed on the upper surface of the light emitting layer 300a, and stepped portions (not shown) may be formed on the side surfaces of the light emitting layer 300a.

As described above, the light emitting layer 300a, the first and second electrodes 314 and 352, and the reflective layer 318 disposed between the first and second passivation layers 316 and 320 that surround the side surfaces and lower surfaces of the light emitting layer 300a and the lower electrode 314, which form the light emitting element 300 (see FIG. 17T), may be formed.

Subsequently, referring to FIG. 17S, among the externally exposed areas, the dummy insulating layer 330a portion disposed between the sacrificial layers 326 is selectively removed by performing the dry etching process.

Next, referring to FIG. 17T, the light emitting element 300 remains on the carrier substrate 350 by removing the remaining sacrificial layers 326 through the wet etching process.

As described above, the process of separating the light emitting element 300 according to another embodiment of the present disclosure from the growth substrate 310 and bonding the light emitting element 300 on the carrier substrate 350 is finished.

Hereinafter, in the display device according to one embodiment of the present specification, a process of transferring the light emitting element formed on the carrier substrate onto the substrate will be described.

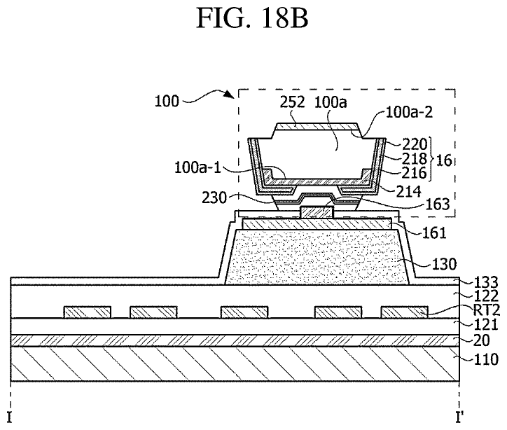

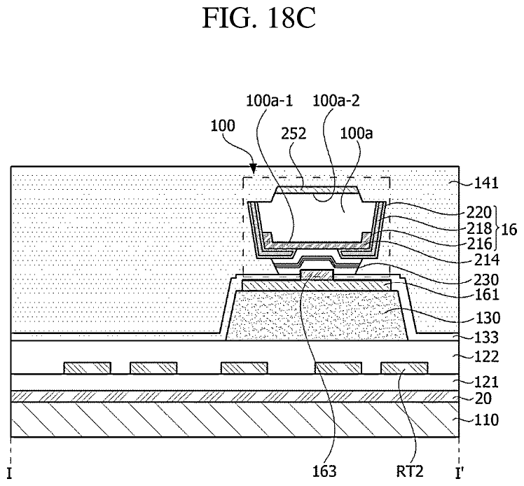

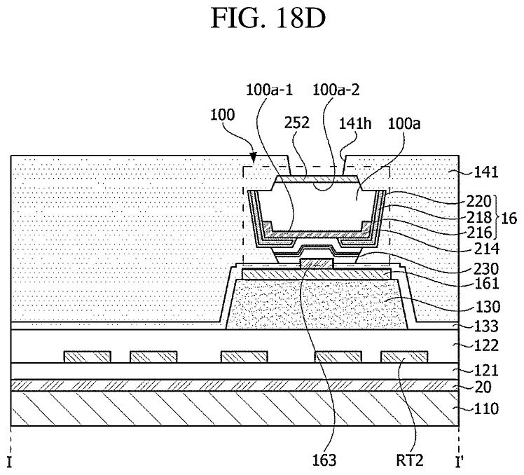

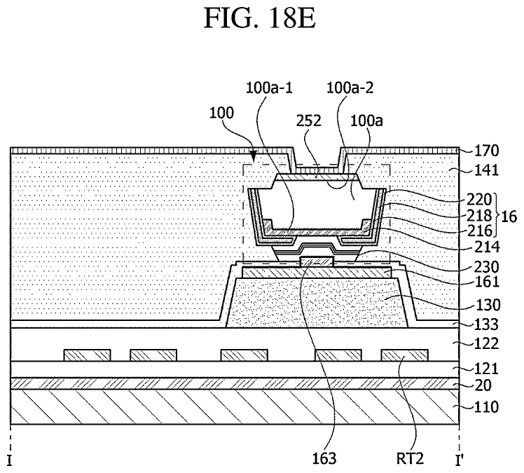

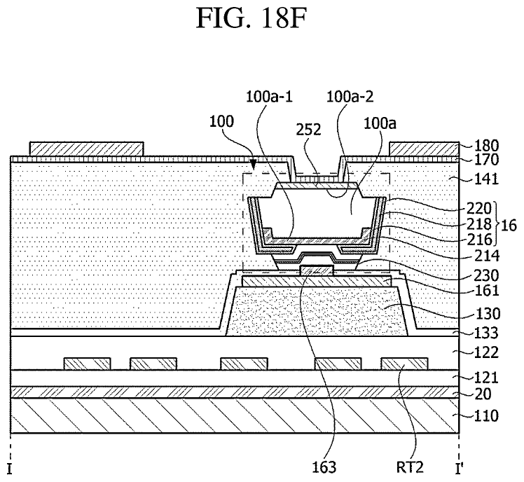

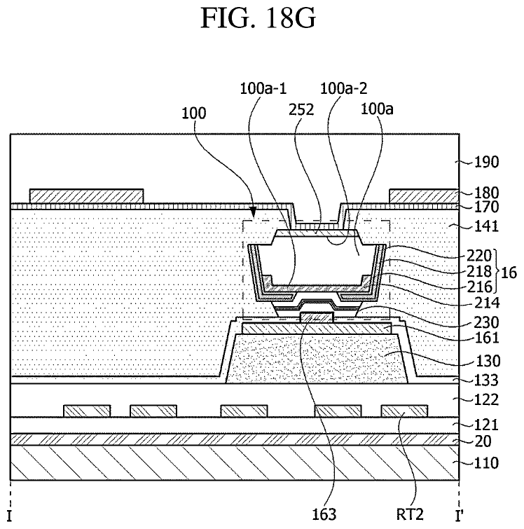

FIGS. 18A to 18G are cross-sectional views for describing a process of manufacturing one pixel in the display device according to one embodiment of the present specification.

Referring to FIG. 18A, the pixel driving circuit 20 is formed on the substrate 110, and the buffer layer 121 that covers the pixel driving circuit 20 is disposed on the substrate 110 including the pixel driving circuit 20.

The substrate 110 may be made of flexible plastic. For example, the substrate 110 may be formed as a single layer or multiple layers made of a material selected from the group consisting of polyimide, polyethylene terephthalate, polyethylene naphthalate, polycarbonate, polyethersulfone, polyarylate, polysulfone, and a cyclic-olefin copolymer, but is not limited thereto. For example, the substrate 110 may be a glass substrate.

The buffer layer 121 may be formed of an inorganic insulating material, such as SiNx or SiO2, in a manner of stacking the inorganic insulating material in multiple layers, and use an organic insulating material and an inorganic insulating material in a manner of stacking the organic insulating material and the inorganic insulating material in multiple layers.

The connection lines RT1 and RT2 may be disposed on the buffer layer 121. The connection lines RT1 and RT2 may be connected to the corresponding signal lines TL1 to TL6 or connected to the signal lines TL1 to TL6. The connection lines RT1 and RT2 may include a plurality of line patterns disposed on different layers with one or more insulating layers interposed there between. The line patterns disposed on different layers may be electrically connected through contact holes passing through the insulating layers formed in subsequent processes.

The connection lines RT1 and RT2 may be single-layer or multilayered metal lines formed of materials selected from the group consisting of aluminum (Al), titanium (Ti), copper (Cu), molybdenum (Mo), tantalum (Ta), titanium nitride (TiN), and tantalum nitride (TaN). For example, the connection lines RT1 and RT2 may be metal lines stacked in a three-layer structure, such as Ti/Al/Ti or Mo/Al/Mo.

The first insulating layer 122 may be disposed on the buffer layer 121 including the connection lines RT1 and RT2. The first insulating layer 122 may be made of an organic insulating material, such as photosensitive photo acryl or photosensitive polyimide, but is not limited thereto. For example, the first insulating layer 122 may include a single or multi insulating layer made of an inorganic insulating material, such as silicon oxide, silicon nitride, silicon oxynitride, or aluminum oxide, but is not limited thereto.

Next, the bank pattern 130 may be formed on the first insulating layer 122. The bank pattern 130 may be made of an organic insulating material, such as photosensitive photo acryl or photosensitive polyimide, but is not limited thereto. The bank pattern 130 may guide an attachment position of the light emitting element in the transfer process of the light emitting element. The bank pattern 130 may be omitted.

Each of the bank patterns 130 may be disposed under one light emitting element 100 (see FIG. 10) or two light emitting elements.

Subsequently, the first electrode 161 may be formed on the bank pattern 130 and the first insulating layer 122.

The first electrode 161, the connection portion 161a, the signal line TL, and/or the connection lines RT1 and RT2 may include a single or multi metal layer formed of materials selected from the group consisting of titanium (Ti), molybdenum (Mo), and aluminum (Al). The first electrode 161, the connection portion 161a, the signal line TL, and/or the connection line RT2 may be formed in a multilayered structure including the first layer ML1, the second layer ML2, the third layer ML3, and the fourth layer ML4.

The first layer ML1 and the third layer ML3 may include titanium (Ti) or molybdenum (Mo). The second layer ML2 may include aluminum (Al). The fourth layer ML4 may include a transparent conductive oxide layer, such as ITO or IZO, which has good adhesion to the solder pattern 163 and also has corrosion resistance and acid resistance.

The first layer ML1, the second layer ML2, the third layer ML3, and the fourth layer ML4 may be sequentially deposited and then patterned by performing a photolithography process and an etching process.

In addition, the contact electrode (not shown, 162 in FIG. 10) is formed on the first insulating layer 122 in an area excluding the bank pattern 130. In this case, the second contact electrode 162 may be made of the same material as the first electrode 161 at the same time.

Subsequently, the solder pattern 163 may be disposed on the first electrode 161. The solder pattern 163 may be made of indium (In), tin (Sn), or an alloy thereof, but is not limited thereto. In the light emitting area, the pad pattern 230 formed on the lower surface of the lower electrode 214 of the light emitting element 100 may be in contact with an upper surface of the solder pattern 163.

Next, the second insulating layer 133 is formed on the solder pattern 163, the first electrode 161, the bank pattern 130, and the first insulating layer 122.

The second insulating layer 133 may be made of an organic insulating material, such as photosensitive photo acryl or photosensitive polyimide, but is not limited thereto. For example, the first insulating layer 122 may include a single or multi insulating layer of an inorganic insulating material, such as silicon oxide, silicon nitride, silicon oxynitride, or aluminum oxide, but is not limited thereto.

Subsequently, the second insulating layer 133 is selectively etched through the patterning process using the photolithography process to expose the upper portions of the solder pattern 163 and/or the first electrode 161. When the second insulating layer 133 is patterned, contact holes (not shown) that expose the upper portions of the solder pattern 163 and/or the first electrode 161 may be formed.

The upper portion of the solder pattern 163 may be exposed by protruding upward from the second insulating layer 133 or exposed in the contact hole of the second insulating layer 133.

Next, although not shown in the drawing, a bonding member (not shown) for transferring the light emitting element 100 may be further formed on the second insulating layer 133 on the substrate 110. However, the present disclosure is not necessarily limited thereto.

Subsequently, referring to FIG. 18B, to transfer the light emitting element 100 onto the second insulating layer 133, the substrate separation process of separating the light emitting element 100 from the carrier substrate 250 (see FIG. 14T). The substrate separation process may use LLO, chemical lift-off (CLO), a method of destroying the insulating layer 236 by applying a pressure with a stamp, or the like.

By performing the substrate separation process, the light emitting element 100 may be separated from the carrier substrate 250 (see FIG. 14T).

Next, the pad pattern 230 formed on the lower surface of the separated light emitting element 100 may be in contact with the solder pattern 163 and the second insulating layer 133 disposed above the bank pattern 130 on the substrate 110 or may be disposed on the solder pattern 163 and the first electrode 161.

The light emitting element 100 may be fixed by a bonding member (not shown) and/or the first electrode 161 and the solder pattern 163.

The lower electrode 214 of each of the light emitting elements 100 may be electrically connected to the anode voltage output terminal of the pixel driving circuit 20 via the solder pattern 163, the first electrode 161, and at least one line pattern through the pad pattern 230 formed on the lower surface of the lower electrode 214. The upper electrode 252 of each of the light emitting elements 100 may be electrically connected to the cathode voltage output terminal of the pixel driving circuit 20 via the second electrode 170, the contact electrode 162, and at least one line pattern.

Next, referring to FIG. 18C, the first interlayer insulating layer 141 is formed on the light emitting element 100 and the second insulating layer 133 on the substrate 110.

The first interlayer insulating layer 141 may cover the plurality of light emitting elements 100 and bank patterns 130. The first interlayer insulating layer 141 may cover the space between the plurality of light emitting elements 100 and the space between the bank patterns 130. The first interlayer insulating layers 141 may extend in the first direction X and may be spaced apart from each other in the second direction Y to be separated between the rows of the pixels.

The light emitted from the plurality of light emitting elements 100 may be scattered by the fine metal particles dispersed in the first interlayer insulating layer 141 and emitted externally.

The first interlayer insulating layer 141 may include an organic insulating material in which fine metal particles, such as titanium dioxide particles, are dispersed.

In addition, the first interlayer insulating layer 141 may be formed by selecting a material with excellent planarization characteristics among organic insulating materials or inorganic insulating materials including an oxide film or a nitride film. However, the present disclosure is not necessarily limited thereto.

Since the first interlayer insulating layer 141 may be formed using a relatively inexpensive material, such as an inorganic insulating material including an oxide film or a nitride film, the first interlayer insulating layer 141 may replace the existing side wall diffuser made of an expensive material, and thus it is possible to reduce the manufacturing process costs.

Although not shown in the drawing, the second interlayer insulating layer (not shown, 142 in FIG. 4) surrounding the periphery of the first interlayer insulating layer 141 may be further formed. The second interlayer insulating layer 142 may be made of an organic insulating material.

The second interlayer insulating layer 142 together with the first interlayer insulating layer 141 may be disposed on the second insulating layer (not shown, 133 in FIG. 4). The first interlayer insulating layer 141 and the second interlayer insulating layer 142 may be made of the same material or different materials. However, the present disclosure is not necessarily limited thereto.

Subsequently, referring to FIG. 18D, the contact hole 141h that exposes the upper electrode 252 of the light emitting element 100 may be formed by selectively removing the first interlayer insulating layer 141 through the mask process.

Next, referring to FIG. 18E, the second electrode 170 in contact with the upper electrode 252 of the light emitting element 100 is formed by forming the second electrode layer (not shown) on the first interlayer insulating layer 141 including the contact hole 141h and patterning the second electrode layer through the photolithography process. The second electrode 170 may be commonly connected to the plurality of pixels (not shown, PXLs in FIG. 2). The second electrode 170 may be a thin electrode through which light is transmitted. The second electrode 170 may be made of a transparent electrode material, such as ITO, but is not necessarily limited thereto.

The second electrodes 170 may each overlap the first interlayer insulating layer 141, and some of the second electrodes 170 may cover the outer surface of the first interlayer insulating layer 141.

The second electrode 170 may be disposed on the first interlayer insulating layer 141 and commonly connected to all pixels PXL. The second electrode 270 may be a thin metal electrode through which light is transmitted. The first electrode 161, the second electrode 170, and the black matrix 180 may be stacked in the non-emission area of the pixel area. The second electrode 170 may be made of a transparent electrode material, such as ITO, but is not necessarily limited thereto.

Next, referring to FIG. 18F, the black matrix 180 is formed on the second electrode 170. The black matrix 180 may be made of an organic insulating material to which black pigment is added.

Subsequently, referring to FIG. 18G, the cover layer 190 is formed on the black matrix 180 and the second electrode 170. The cover layer 190 may be made of an organic insulating material that covers the black matrix 180 and the second electrode 170.

An insulating layer that is the same as the first interlayer insulating layer 141 may be formed flat between the cover layer 190 and the second electrode 170. In this case, the insulating layer made of an organic insulating material may cover the second electrode 170 in a smaller thickness than the first interlayer insulating layer 141.

As described above, when the light emitting element 100 is transferred onto the substrate 110, the lower electrode 214 is connected to the pixel electrode (not shown) through the pad pattern 230, and thus a positive voltage is applied to the lower electrode 214 through the pixel electrode, and a negative voltage is applied to the upper electrode 252 through the second electrode 170. Therefore, a current flows between the pixel electrode (not shown) and the second electrode 170 by the movement of electrons of the second conductive semiconductor layer and the flow of holes of the first conductive semiconductor layer.

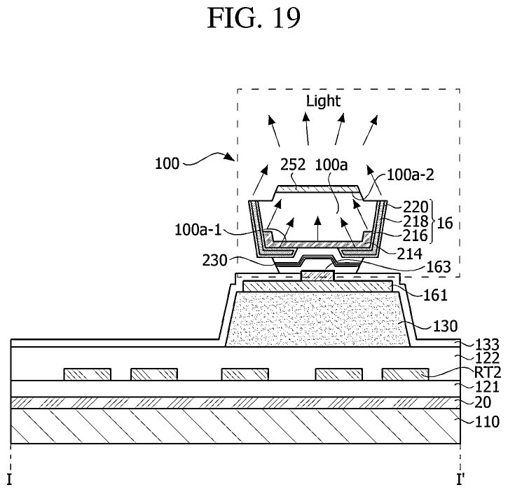

FIG. 19 is a cross-sectional view schematically showing a state in which light is reflected in and emitted from the light emitting element of the display device according to one embodiment of the present specification.

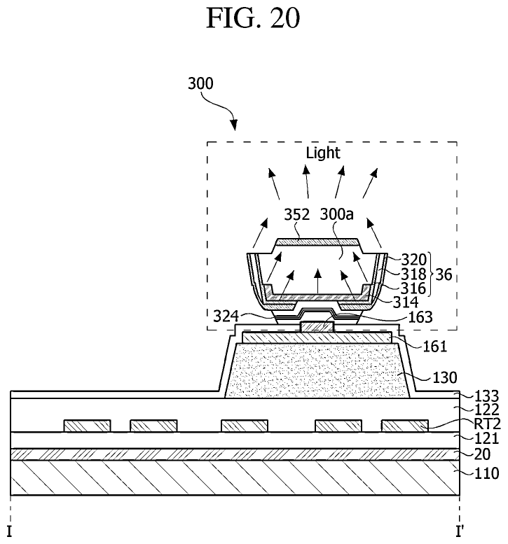

FIG. 20 is a cross-sectional view schematically showing a state in which light is reflected in and emitted from the light emitting element of the display device according to another embodiment of the present specification.

Referring to FIG. 19, it can be seen that the light generated in the light emitting element 100 of the display device according to one embodiment of the present specification is reflected by the reflective layer 218 of the reflector 16 disposed on the side surfaces and lower surface in the light emitting element 100 and emitted upward, thereby increasing luminous efficiency.

Since the reflective layer 218 is disposed between the first and second passivation layers 216 and 220 disposed to surround the side surfaces and lower surface of the light emitting element 100, it is possible to allow the light generated inside the light emitting element 100 to be reflected by the reflective layer 218 and effectively emitted upward from the light emitting element 100.

Referring to FIG. 20, it can be seen that the light generated in the light emitting element 300 of the display device according to another embodiment of the present specification is reflected by the reflective layer 318 of the reflector 16 disposed on the side surfaces in the light emitting element 300 and emitted upward, thereby increasing luminous efficiency.

Since the reflective layer 318 is disposed between the first and second passivation layers 316 and 320 disposed to surround the side surfaces of the light emitting element 300, it is possible to allow the light generated inside the light emitting element 300 to be reflected by the reflective layer 318 and effectively emitted upward from the light emitting element 300.

Referring to FIGS. 19 and 20, at least some light generated from the light emitting layers 100a and 300a passes through the first electrodes 214 and 314, is reflected from the reflective layers 218 and 318, passes through the first electrodes 214 and 314, the light emitting layers 100a and 300a, and the second electrodes 252 and 352 and is emitted to the outside.

In addition, conventionally, since the process of patterning a portion of the reflective layer disposed under the light emitting element is required to form the reflective mirror, the process margin is formed narrow.

However, in the present disclosure, the process of forming the reflective mirror under the light emitting elements 100 and 300 is omitted, the first and second passivation layers that surround the outer surface of the light emitting element are disposed on the side surfaces of the light emitting element, and the reflective layer replaced with the reflective mirror is formed between the first and second passivation layers, and thus it is possible to solve the conventional problem that the process margin becomes narrow.

In one embodiment of the present specification, since the reflective layer is disposed inside the light emitting element to increase luminous efficiency inside the light emitting element, it is possible to increase luminous efficiency even with low power consumption, thereby increasing yield.

In addition, in one embodiment of the present specification, since a patterning process for forming the reflective layer inside the light emitting element to form the reflective mirror or the like can be omitted, it is possible to simplify a manufacturing process.

Furthermore, in one embodiment of the present specification, since the reflective layer is disposed in the light emitting element to increase luminous efficiency even without the side wall diffuser made of an expensive material for increasing luminous efficiency, it is possible to reduce manufacturing process costs.

In the present specification, since the reflective layer is formed in the light emitting element to allow light to be directly reflected in the light emitting element, it is possible to increase luminous efficiency.

In the present specification, since a process of forming the reflective mirror above a bank pattern may be omitted, it is possible to simplify the process and fundamentally prevent or at least reduce process margin defects.

In the present specification, since the reflective layer is disposed inside the light emitting element to increase luminous efficiency, the side wall diffuser made of an expensive material with excellent luminous efficiency does not need to be used, and thus it is possible to reduce a process material.

In addition, in one embodiment of the present specification, since a patterning process of forming the reflective layer under the light emitting element to form the reflective mirror, or the like may be omitted, it is possible to simplify a manufacturing process.

The display device according to various embodiments of the present disclosure may be described as follows.

A display device according to one embodiment of the present specification may comprise a first electrode, a second electrode, a light emitting layer disposed between the first electrode and the second electrode, and a reflector that covers side surfaces of the light emitting layer and at least a portion of side surfaces of the first electrode, wherein the reflector includes a first insulating layer, a second insulating layer, and a metal layer disposed between the first insulating layer and the second insulating layer.

According to the display device according to one or more embodiments of the present disclosure, the metal layer may be disposed between the first insulating layer and the second insulating layer to overlap the side surfaces and a lower surface of the light emitting layer or overlap the side surfaces of the light emitting layer.

According to the display device according to one or more embodiments of the present disclosure, the light emitting element may include a lower surface of the light emitting layer on which the first electrode is disposed, an upper surface of the light emitting layer on which the second electrode is disposed; and the side surfaces of the light emitting layer between the lower surface and the upper surface, the lower and upper surfaces of the light emitting layer include first and second flat protrusions on which the first and second electrodes are disposed, and stepped portions disposed at edges of the first and second flat protrusions, the stepped portions have smaller heights than the first and second flat protrusions, and the reflector is disposed on at least a portion of the side surfaces of the light emitting layer under the stepped portion.

According to the display device according to one or more embodiments of the present disclosure, a lower surface of the light emitting layer on which the first electrode of the light emitting element may be disposed and the upper surface of the light emitting layer on which the second electrode is disposed have smaller widths than the side surfaces between the upper surface and the lower surface of the light emitting layer.

A display device according to one or more embodiments of the present disclosure may include a display panel on which a plurality of sub-pixels and lines connected to the sub-pixels are disposed, and a pixel driving circuit configured to drive the sub-pixels, wherein the display panel further includes a plurality of protruded bank patterns disposed in the sub-pixels, and a light emitting element disposed in each of the bank patterns, the light emitting element includes a first electrode, a second electrode, a light emitting layer disposed between the first electrode and the second electrode, and a reflector that covers side surfaces of the light emitting layer and at least a portion of side surfaces of the first electrode, and the reflector includes a first insulating layer, a second insulating layer, and a metal layer disposed between the first insulating layer and the second insulating layer.

According to display device according to one or more embodiments of the present disclosure, the metal layer may be disposed between the first insulating layer and the second insulating layer to overlap the side surfaces and a lower surface of the light emitting element or overlap the side surfaces of the light emitting element.

According to the display device according to one or more embodiments of the present disclosure, the first and second insulating layers may be made of any one selected from an inorganic insulating material or an organic insulating material or made of an oxide including at least one of Ni, Ti, Pt, Pd, Cu, CuW, Mo, MoW, Ag, Al, Hf, Zr, and Ta.

According to the display device according to one or more embodiments of the present disclosure, the light emitting element may include a lower surface of the light emitting layer on which the first electrode is disposed, an upper surface of the light emitting layer on which the second electrode is disposed, and the side surfaces of the light emitting layer between the lower surface and the upper surface, the lower and upper surfaces of the light emitting layer include first and second protrusions on which the first and second electrodes are disposed, and stepped portions disposed at edges of the first and second protrusions, the stepped portions have smaller heights than the first and second protrusions, and the reflector is disposed on at least a portion of the side surfaces of the light emitting element under the stepped portion.

According to the display device according to one or more embodiments of the present disclosure, a lower surface of the light emitting layer on which the first electrode may be disposed and the upper surface of the light emitting layer on which the second electrode is disposed have smaller widths than the side surfaces between the upper surface and the lower surface of the light emitting layer.

According to the display device according to one or more embodiments of the present disclosure, an area of the light emitting element is smaller than or equal to an area of the bank pattern.

According to the display device according to one or more embodiments of the present disclosure, the light emitting element may be connected to an electrode line and a solder pattern that are disposed on the bank pattern by a pad pattern disposed on a lower surface of the first electrode.

According to the display device according to one or more embodiments of the present disclosure, the area of the light emitting element may be smaller than or equal to an area of the electrode line.

According to the display device according to one or more embodiments of the present disclosure, an interlayer insulating layer may be disposed on an entire surface of a substrate including the light emitting element.

According to the display device according to one or more embodiments of the present disclosure, the interlayer insulating layer may have a stacked structure of any one or more of an organic insulating material and an inorganic insulating material including an oxide film or a nitride film.

A method of manufacturing a display device according to one or more embodiments of the present disclosure may comprise forming a light emitting layer on a substrate, forming a first electrode layer under the light emitting layer, forming a first insulating layer and a second insulating layer on side surfaces of the light emitting layer and at least a portion of side surfaces of the first electrode, forming a reflective layer between the first insulating layer and the second insulating layer, and forming a second electrode on the light emitting layer.

According to the method of manufacturing a display device according to one or more embodiments of the present disclosure, the reflective layer may be formed to overlap the side surfaces of the light emitting layer and the side surfaces and a lower surface of the first electrode or formed to overlap the side surfaces of the light emitting layer and the side surfaces of the first electrode.

According to the method of manufacturing a display device according to one or more embodiments of the present disclosure, the forming of the reflective layer may include forming the first insulating layer on the light emitting layer and the first electrode, forming a metal layer on the first insulating layer, exposing a portion of the first electrode by patterning the metal layer and the first insulating layer, and forming the second insulating layer on the patterned metal layer and the exposed first electrode and forming the reflective layer between the first insulating layer and the second insulating layer.

According to the method of manufacturing a display device according to one or more embodiments of the present disclosure, the forming of the reflective layer may include forming the first insulating layer on the light emitting layer and the first electrode, forming a metal layer on the first insulating layer, patterning the metal layer and the first insulating layer and forming the reflective layer on the side surfaces of the light emitting layer and the first electrode, and forming the second insulating layer on the first insulating layer formed on the reflective layer and the side surfaces and a lower surface of the first electrode.

According to the method of manufacturing a display device according to one or more embodiments of the present disclosure, the metal layer may be patterned through an etch back process to form the reflective layer between the first insulating layer and the second insulating layer that are formed on the side surfaces of the light emitting layer and the first electrode.

According to the method of manufacturing a display device according to one or more embodiments of the present disclosure may further comprise removing a portion of the light emitting layer under both sides of the second electrode.

According to the method of manufacturing a display device according to one or more embodiments of the present disclosure, a protrusion may be formed on an upper surface of the light emitting layer on which the second electrode is formed by removing a portion of the upper surface of the light emitting layer, and stepped portions are formed on side surfaces of the protrusion of the light emitting layer.

A method of manufacturing a display device according to one or more embodiments of the present disclosure may comprise forming a display panel on which a plurality of sub-pixels and lines connected to the sub-pixels are disposed, and forming a pixel driving circuit configured to drive the sub-pixels, wherein the forming of the display panel further includes forming a plurality of protruded bank patterns disposed in the sub-pixels, and forming a light emitting element disposed in each of the bank patterns, the forming of the light emitting element includes forming a first electrode and a second electrode, forming a light emitting layer disposed between the first electrode and the second electrode, and forming a reflector that covers side surfaces of the light emitting layer and at least a portion of side surfaces of the first electrode, and the forming of the reflector includes forming a first insulating layer and a second insulating layer on side surfaces of the light emitting element, and forming a metal layer between the first insulating layer and the second insulating layer.

According to the method of manufacturing a display device according to one or more embodiments of the present disclosure, the metal layer may be disposed between the first insulating layer and the second insulating layer to overlap the side surfaces and a lower surface of the light emitting element or overlap the side surfaces of the light emitting element.

According to the method of manufacturing a display device according to one or more embodiments of the present disclosure, the light emitting element may include a lower surface of the light emitting layer on which the first electrode is disposed, an upper surface of the light emitting layer on which the second electrode is disposed, and the side surfaces of the light emitting layer between the lower surface and the upper surface, the lower and upper surfaces of the light emitting layer include first and second flat protrusions on which the second electrode is disposed, and stepped portions disposed at edges of the first and second flat protrusions, the stepped portions have smaller heights than the first and second flat protrusions, and the metal layers are disposed on at least a portion of the side surfaces of the light emitting element under the stepped portions.

According to the method of manufacturing a display device according to one or more embodiments of the present disclosure, a lower surface of the light emitting layer on which the first electrode of the light emitting element may be disposed and the upper surface of the light emitting layer on which the second electrode is disposed have smaller widths than the side surfaces between the upper surface and the lower surface of the light emitting layer.

According to the method of manufacturing a display device according to one or more embodiments of the present disclosure, an area of the light emitting element may be smaller than or equal to an area of the bank pattern.

According to the method of manufacturing a display device according to one or more embodiments of the present disclosure may further include forming a pad pattern on a lower surface of the first electrode, and forming an electrode line and a solder pattern to which the light emitting element is connected by the pad pattern on the bank pattern.

According to the method of manufacturing a display device according to one or more embodiments of the present disclosure may further include forming an interlayer insulating layer on the substrate including the light emitting element.

A method of manufacturing a display device according to one or more embodiments of the present disclosure, the interlayer insulating layer may have a stacked structure of any one or more of an organic insulating material and an inorganic insulating material including an oxide film or a nitride film.

The effects of the present specification are not limited to the above-described effects, and other effects that are not mentioned will be able to be clearly understood by those skilled in the art from the above detailed description.

Since the contents of the specification described in the above-described problems to be solved, means to solve the problems, and effects do not specify the essential features of the claims, the scope of the claims is not limited by the items described in the contents of the specification.

Although embodiments of the present disclosure have been described in more detail with reference to the accompanying drawings, the present disclosure is not necessarily limited to the embodiments, and various modifications may be carried out without departing from the technical spirit of the present disclosure. Therefore, the embodiments disclosed in the present disclosure are not intended to limit the technical spirit of the present disclosure, but intended to describe the same, and the scope of the technical spirit of the present disclosure is not limited by these embodiments. Therefore, it should be understood that the above-described embodiments are illustrative and not restrictive in all respects.

What is claimed is:

1. A display device including a light emitting element, comprising:
a first electrode;
a second electrode;
a light emitting layer between the first electrode and the second electrode; and
a reflector that covers side surfaces of the light emitting layer and at least a portion of side surfaces of the first electrode,
wherein the reflector includes:
a first insulating layer;
a second insulating layer; and
a metal layer between the first insulating layer and the second insulating layer.

2. The display device of claim 1, wherein the metal layer is between the first insulating layer and the second insulating layer, the metal layer overlapping the side surfaces and a lower surface of the light emitting layer, or overlapping the side surfaces of the light emitting layer.

3. The display device of claim 1, wherein the light emitting element includes:
a lower surface on which the first electrode is disposed; and
an upper surface on which the second electrode is disposed;
wherein the side surfaces of the light emitting layer are between the lower surface and the upper surface,
wherein the lower surface and the upper surface of the light emitting layer include:
a first flat protrusion and a second flat protrusion on which the first electrode and the second electrode are disposed; and
stepped portions at edges of the first flat protrusion and the second flat protrusion,
the stepped portions have smaller heights than the first flat protrusion and the second flat protrusion, and
the reflector is disposed on at least a portion of the side surfaces of the light emitting layer under the stepped portions.

4. The display device of claim 1, wherein a lower surface of the light emitting layer on which the first electrode of the light emitting element is disposed and an upper surface of the light emitting layer on which the second electrode is disposed have smaller widths than the side surfaces of the light emitting element between the upper surface and the lower surface of the light emitting layer.

5. A display device comprising:
a display panel on which a plurality of sub-pixels and lines connected to the plurality of sub-pixels are disposed; and
a pixel driving circuit configured to drive the plurality of sub-pixels,
wherein the display panel further includes:
a plurality of protruded bank patterns in the plurality of sub-pixels; and
a light emitting element in each of the plurality of protruded bank patterns,
wherein the light emitting element in a bank pattern from the plurality of protruded bank patterns includes:
a first electrode;
a second electrode;
a light emitting layer between the first electrode and the second electrode; and
a reflector that covers side surfaces of the light emitting layer and at least a portion of side surfaces of the first electrode, and
wherein the reflector includes:
a first insulating layer;
a second insulating layer; and
a metal layer between the first insulating layer and the second insulating layer.

6. The display device of claim 5, wherein the metal layer is between the first insulating layer and the second insulating layer, the metal layer overlapping the side surfaces and a lower surface of the light emitting element, or overlapping the side surfaces of the light emitting element.

7. The display device of claim 5, wherein the first insulating layer and the second insulating layer comprise an inorganic insulating material or an organic insulating material or an oxide including at least one of Ni, Ti, Pt, Pd, Cu, CuW, Mo, MoW, Ag, Al, Hf, Zr, or Ta.

8. The display device of claim 5, wherein the light emitting element includes:
a lower surface on which the first electrode is disposed; and
an upper surface on which the second electrode is disposed;
wherein the side surfaces of the light emitting layer between the lower surface and the upper surface,
wherein the lower surface and the upper surface of the light emitting layer include:
a first protrusion and a second protrusion on which the first electrode and the second electrode are disposed; and
stepped portions at edges of the first protrusion and the second protrusion,
wherein the stepped portions have smaller heights than the first protrusion and the second protrusion, and
wherein the reflector is disposed on at least a portion of the side surfaces of the light emitting element under the stepped portions.

9. The display device of claim 5, wherein a lower surface of the light emitting layer on which the first electrode is disposed and an upper surface of the light emitting layer on which the second electrode is disposed have smaller widths than the side surfaces of the light emitting layer between the upper surface and the lower surface of the light emitting layer.

10. The display device of claim 5, wherein an area of the light emitting element is smaller than or equal to an area of the bank pattern.

11. The display device of claim 5, wherein the light emitting element is connected to an electrode line and a solder pattern by a pad pattern on a lower surface of the first electrode, and
wherein the electrode line and the solder pattern are on the bank pattern.

12. The display device of claim 11, wherein an area of the light emitting element is smaller than or equal to an area of the electrode line.

13. The display device of claim 5, wherein an interlayer insulating layer is on an entire surface of a substrate including the light emitting element.

14. The display device of claim 13, wherein the interlayer insulating layer comprises a stacked structure, the stacked structure including one or more of an organic insulating material and an inorganic insulating material including an oxide film or a nitride film.

15. A method of manufacturing a display device including a light emitting element, comprising:
forming a light emitting layer on a substrate;
forming a first electrode under the light emitting layer;
forming a first insulating layer and a second insulating layer on side surfaces of the light emitting layer and at least a portion of side surfaces of the first electrode;
forming a reflective layer between the first insulating layer and the second insulating layer; and
forming a second electrode on the light emitting layer.

16. The method of claim 15, wherein the reflective layer is formed to overlap the side surfaces of the light emitting layer and the side surfaces and a lower surface of the first electrode, or formed to overlap the side surfaces of the light emitting layer and the side surfaces of the first electrode.

17. The method of claim 15, wherein forming of the reflective layer includes:
forming the first insulating layer on the light emitting layer and the first electrode;
forming a metal layer on the first insulating layer;
exposing a portion of the first electrode by patterning the metal layer and the first insulating layer;
forming the second insulating layer on the patterned metal layer and the exposed first electrode; and
forming the reflective layer between the first insulating layer and the second insulating layer.

18. The method of claim 15, wherein forming of the reflective layer includes:
forming the first insulating layer on the light emitting layer and the first electrode;
forming a metal layer on the first insulating layer;
patterning the metal layer and the first insulating layer;
forming the reflective layer on the side surfaces of the light emitting layer and the first electrode; and
forming the second insulating layer on the first insulating layer, the first insulating layer formed on the reflective layer and the side surfaces and a lower surface of the first electrode.

19. The method of claim 18, wherein the metal layer is patterned through an etch back process to form the reflective layer between the first insulating layer and the second insulating layer that are formed on the side surfaces of the light emitting layer and the first electrode.

20. The method of claim 15, further comprising:
removing a portion of the light emitting layer under both sides of the second electrode.

21. The method of claim 20, wherein a protrusion is formed on an upper surface of the light emitting layer on which the second electrode is formed by removing a portion of the upper surface of the light emitting layer, and stepped portions are formed on side surfaces of the protrusion of the light emitting layer.

22. A method of manufacturing a display device, comprising:
forming a display panel on which a plurality of sub-pixels and lines connected to the plurality of sub-pixels are disposed; and
forming a pixel driving circuit configured to drive the plurality of sub-pixels,
wherein the forming of the display panel further includes:
forming a plurality of protruded bank patterns in the plurality of sub-pixels; and
forming a light emitting element in each of the plurality of protruded bank patterns,
wherein the forming of the light emitting element in a bank pattern from the plurality of protruded bank patterns includes:
forming a first electrode and a second electrode;
forming a light emitting layer disposed between the first electrode and the second electrode; and
forming a reflector that covers side surfaces of the light emitting layer and at least a portion of side surfaces of the first electrode, and
wherein the forming of the reflector includes:
forming a first insulating layer and a second insulating layer on side surfaces of the light emitting element; and
forming a metal layer between the first insulating layer and the second insulating layer.

23. The method of claim 22, wherein the metal layer is between the first insulating layer and the second insulating layer, the metal layer overlapping the side surfaces and a lower surface of the light emitting element or overlapping the side surfaces of the light emitting element.

24. The method of claim 22, wherein the light emitting element includes:
a lower surface of the light emitting layer on which the first electrode is disposed;
an upper surface of the light emitting layer on which the second electrode is disposed; and
wherein the side surfaces of the light emitting layer is between the lower surface and the upper surface,
wherein the lower surface and the upper surface of the light emitting layer include:
first flat protrusion and second flat protrusion on which the second electrode is disposed; and
stepped portions at edges of the first flat protrusion and the second flat protrusion,
the stepped portions have smaller heights than the first flat protrusion and second flat protrusion, and
the metal layer is on at least a portion of the side surfaces of the light emitting element under the stepped portions.

25. The method of claim 22, wherein a lower surface of the light emitting layer on which the first electrode of the light emitting element is disposed and an upper surface of the light emitting layer on which the second electrode is disposed have smaller widths than the side surfaces of the light emitting layer between the upper surface and the lower surface of the light emitting layer.

26. The method of claim 22, wherein an area of the light emitting element is smaller than or equal to an area of the bank pattern.

27. The method of claim 22, further comprising:
forming a pad pattern on a lower surface of the first electrode; and
forming an electrode line and a solder pattern by the pad pattern on the bank pattern,
the electrode line and the solder pattern connected to the light emitting element.

28. The method of claim 22, further comprising forming an interlayer insulating layer on a substrate including the light emitting element.

29. The method of claim 28, wherein the interlayer insulating layer comprises a stacked structure, the interlayer insulating layer including one or more of an organic insulating material and an inorganic insulating material, the inorganic insulating material including an oxide film or a nitride film.
